(19) United States
(12) Patent Application Publication
(10) Pub. No.: US 2023/0420324 A1
(43) Pub. Date: Dec. 28, 2023

(54) SEMICONDUCTOR DEVICE AND MANUFACTURING METHOD FOR SEMICONDUCTOR DEVICE

(71) Applicant: ROHM CO., LTD., Kyoto-shi (JP)

(72) Inventors: Takayuki OSAWA, Kyoto-shi (JP); Takeshi OKAMOTO, Kyoto-shi (JP)

(73) Assignee: ROHM CO., LTD., Kyoto-shi (JP)

(21) Appl. No.: 18/465,192

(22) Filed: Sep. 12, 2023

Related U.S. Application Data
(63) Continuation of application No. PCT/JP2022/006443, filed on Feb. 17, 2022.

(30) Foreign Application Priority Data
Mar. 17, 2021 (JP) 2021-043960

(51) Int. Cl. H01L 23/31; H01L 29/06; H01L 29/40; H01L 29/417; H01L 29/739; H01L 21/02; H01L 21/311; H01L 29/66

(52) U.S. Cl. CPC H01L 23/3192; H01L 23/3171; H01L 29/0623; H01L 29/402; H01L 29/41708; H01L 29/7397; H01L 21/02236; H01L 21/02255; H01L 21/02271; H01L 21/31111; H01L 21/31116; H01L 21/31144; H01L 29/6634; H01L 29/66348

(57) ABSTRACT

An outer peripheral region of this semiconductor device comprises: a guard ring; an insulating film and an intermediate insulating film that cover a surface of the guard ring; a field plate; a passivation film provided so as to cover both the insulating film and the field plate; and a barrier layer that has a smaller diffusion coefficient than the insulating film and the intermediate insulating film, and than the passivation film. The field plate includes a first section provided within an opening in the insulating film and the intermediate insulating film, and a second section having a protrusion that protrudes outward beyond the first section. The barrier layer has a section that is inserted between the protrusion and the guard ring.

### CROSS-REFERENCE TO RELATED APPLICATIONS

This application is a continuation of International Application No. PCT/JP2022/006443, filed Feb. 17, 2022, which claims priority to JP 2021-043960, filed Mar. 17, 2021, the entire contents of each are incorporated herein by reference.

### BACKGROUND

The present disclosure relates to a semiconductor device and a method for manufacturing a semiconductor device.

An example of a semiconductor device is an insulated gate bipolar transistor (IGBT) used in an in-vehicle inverter and includes a protection film formed on an electrode. (for example, refer to Japanese Laid-Open Patent Publication No. 2020-136472).

### BRIEF DESCRIPTION OF DRAWINGS

FIG. 1 is a plan view showing a first embodiment of a semiconductor device.

FIG. 2 is a plan view of the semiconductor device shown in FIG. 1 with a protection film removed.

FIG. 3 is a cross-sectional view showing an example of the cross-sectional structure of a cell region.

FIG. 4 is a cross-sectional view taken along line 4-4 in FIG. 1 showing the cross-sectional structure of the semiconductor device.

FIG. 5 is an enlarged view of a gate finger and an emitter extension shown in FIG. 4.

FIG. 6 is an enlarged partial view of a field limiting ring (FLR) portion shown in FIG. 4.

FIG. 7 is an enlarged view of an equipotential ring shown in FIG. 4.

FIG. 8 is a diagram showing an example of a manufacturing step in a method for manufacturing a first embodiment of a semiconductor device.

FIG. 9 is a diagram showing an example of a manufacturing step in the method for manufacturing the semiconductor device.

FIG. 10 is a diagram showing an example of a manufacturing step in the method for manufacturing the semiconductor device.

FIG. 11 is a diagram showing an example of a manufacturing step in the method for manufacturing the semiconductor device.

FIG. 12 is a diagram showing an example of a manufacturing step in the method for manufacturing the semiconductor device.

FIG. 13 is a diagram showing an example of a manufacturing step in the method for manufacturing the semiconductor device.

FIG. 14 is a diagram showing an example of a manufacturing step in the method for manufacturing the semiconductor device.

FIG. 15 is a diagram showing an example of a manufacturing step in the method for manufacturing the semiconductor device.

FIG. 16 is a diagram showing an example of a manufacturing step in the method for manufacturing the semiconductor device.

FIG. 17 is a diagram showing an example of a manufacturing step in the method for manufacturing the semiconductor device.

FIG. 18 is a diagram showing an example of a manufacturing step in the method for manufacturing the semiconductor device.

FIG. 19 is a diagram showing an example of a manufacturing step in the method for manufacturing the semiconductor device.

FIG. 20 is a diagram showing an example of a manufacturing step in the method for manufacturing the semiconductor device.

FIG. 21 is a cross-sectional view showing a partial cross-sectional structure of an FLR portion in a second embodiment of a semiconductor device.

FIG. 22 is a cross-sectional view showing an example of the cross-sectional structure of a cell region.

FIG. 23 is a diagram showing an example of a manufacturing step in a method for manufacturing the semiconductor device of the second embodiment.

FIG. 24 is a diagram showing an example of a manufacturing step in the method for manufacturing the semiconductor device.

FIG. 25 is a diagram showing an example of a manufacturing step in the method for manufacturing the semiconductor device.

FIG. 26 is a cross-sectional view showing a partial cross-sectional structure of an FLR portion in a third embodiment of a semiconductor device.

FIG. 27 is a diagram showing an example of a manufacturing step in a method for manufacturing the semiconductor device of the third embodiment.

FIG. 28 is a diagram showing an example of a manufacturing step in the method for manufacturing the semiconductor device.

FIG. 29 is a diagram showing an example of a manufacturing step in the method for manufacturing the semiconductor device.

FIG. 30 is a diagram showing an example of a manufacturing step in the method for manufacturing the semiconductor device.

FIG. 31 is a diagram showing an example of a manufacturing step in the method for manufacturing the semiconductor device.

FIG. 32 is a diagram showing an example of a manufacturing step in the method for manufacturing the semiconductor device.

FIG. 33 is a diagram showing an example of a manufacturing step in the method for manufacturing the semiconductor device.

FIG. 34 is a cross-sectional view showing a partial cross-sectional structure of an FLR portion in a modified example of a semiconductor device.

FIG. 35 is a cross-sectional view showing a partial cross-sectional structure of a peripheral portion in a modified example of a semiconductor device.

### DETAILED DESCRIPTION

Embodiments of a semiconductor device will be described below with reference to the drawings. The embodiments described below exemplify configurations and methods for embodying a technical concept and are not intended to limit the material, shape, structure, layout, dimensions, and the like of each component to those described below.

### First Embodiment

Structure of Semiconductor Device

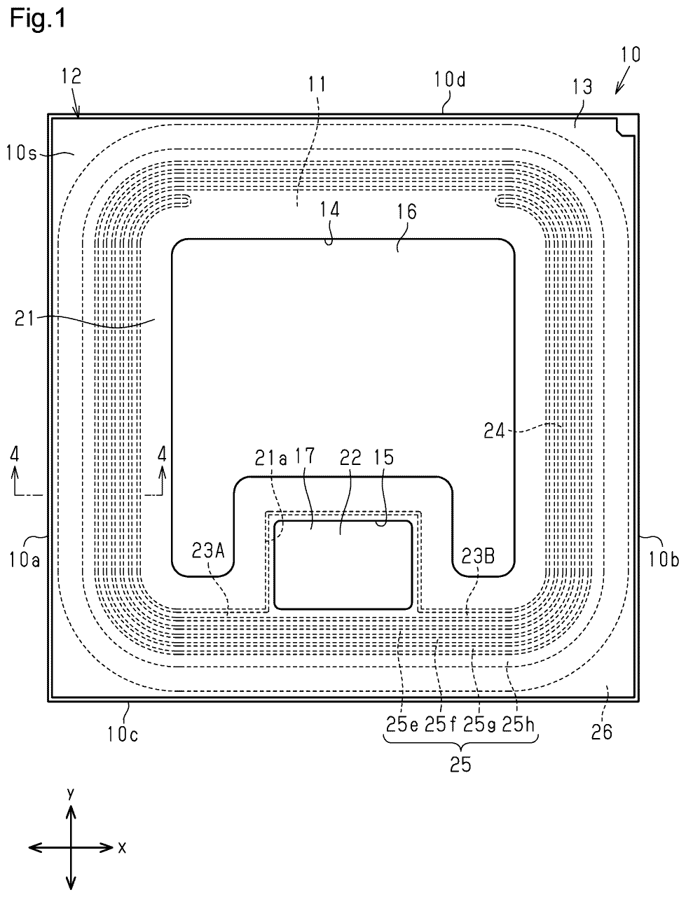

The structure of a first embodiment of a semiconductor device 10 will now be described with reference to FIGS. 1 to 7.

The semiconductor device 10 of the present embodiment is a trench-gate insulated gate bipolar transistor (IGBT). In an example, the semiconductor device 10 is used as a switching element mounted on an in-vehicle inverter. In this case, the semiconductor device 10 receives a current of, for example, greater than or equal to 5 A and less than or equal to 1000 A.

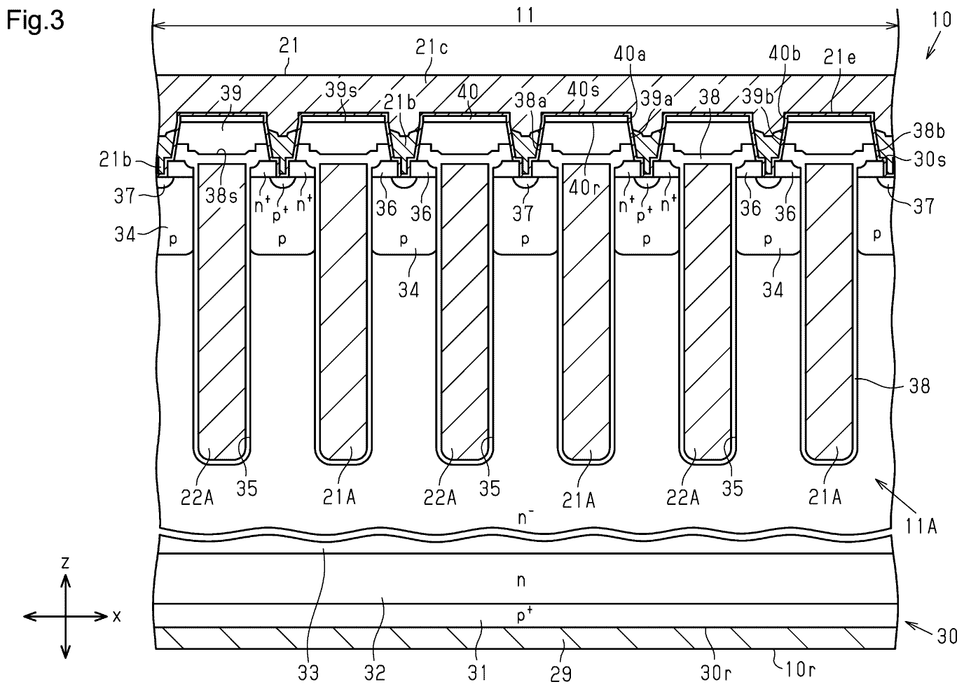

As shown in FIG. 1, the semiconductor device 10 is, for example, rectangular and flat. In the present embodiment, the semiconductor device 10 includes a device main surface 10s that is, for example, square. In the present embodiment, each side of the device main surface 10s has a length of approximately 11 mm. That is, in the present embodiment, the chip size of the semiconductor device 10 is 11 mm-square. The semiconductor device 10 includes a device back surface 10r opposite to the device main surface 10s (refer to FIG. 3), and four device side surfaces 10a to 10d formed between the device main surface 10s and the device back surface 10r. In an example, the device side surfaces 10a to 10d join the device main surface 10s and the device back surface 10r and are orthogonal to both the device main surface 10s and the device back surface 10r.

In the following description, a direction in which the device main surface 10s and the device back surface 10r face is referred to as a “z-direction.” The z-direction may also be referred to as a height-wise direction of the semiconductor device 10. Two directions that are orthogonal to each other and orthogonal to the z-direction are referred to as an “x-direction” and a “y-direction.” In the present embodiment, the device side surfaces 10a and 10b define opposite end surfaces of the semiconductor device 10 in the x-direction. The device side surfaces 10c and 10d define opposite end surfaces of the semiconductor device 10 in the y-direction. In the following description, a direction from the device back surface 10r toward the device main surface 10s is referred to as an upward direction, and a direction from the device main surface 10s toward the device back surface 10r is referred to as a downward direction.

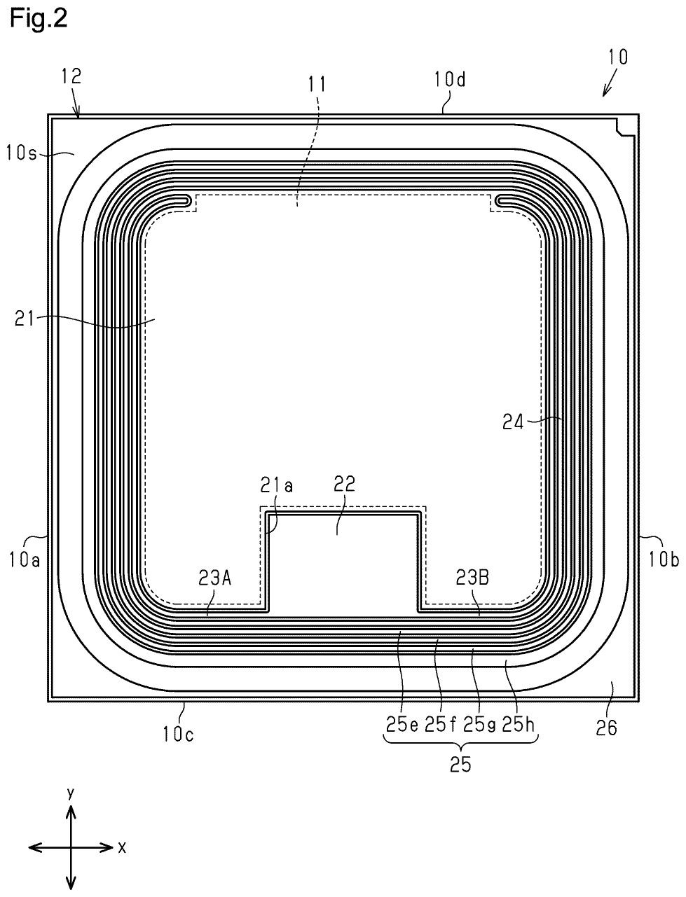

As shown in FIG. 2, the semiconductor device 10 includes an emitter electrode 21 and a gate electrode 22 that are used as external electrodes configured to be connected to an external device of the semiconductor device 10.

The emitter electrode 21 includes the emitter of an IGBT. The emitter electrode 21 includes an accommodation recess 21a recessed in the y-direction. The accommodation recess 21a is open toward the device side surface 10c.

The gate electrode 22 includes the gate of an IGBT and receives a drive voltage signal for driving the semiconductor device 10 from the outside of the semiconductor device 10. The gate electrode 22 is located adjacent to the emitter electrode 21 in the y-direction. The gate electrode 22 is arranged in the accommodation recess 21a of the emitter electrode 21.

As indicated by broken lines in FIG. 2, the semiconductor device 10 includes a cell region 11 including cells and a peripheral region 12 arranged at an outer side of the cell region 11 and surrounding the cell region 11. The cell refers to a main cell on which a transistor is formed. That is, the cell region 11 is a region in which a transistor is formed. The peripheral region 12 is formed on a peripheral portion of the device main surface 10s as viewed in the z-direction. The peripheral region 12 is a region surrounding the emitter electrode 21 and excluding the region of the gate electrode 22.

The emitter electrode 21 is arranged in the cell region 11. The emitter electrode 21 is formed on a large portion of the cell region 11. As viewed in the z-direction, the cell region 11 is shaped in conformance with the shape of the emitter electrode 21.

The peripheral region 12 includes a termination structure that improves the dielectric strength of the semiconductor device 10. The peripheral region 12 is a region surrounding the emitter electrode 21 and excluding the region of the gate electrode 22. The gate electrode 22 is arranged in a region surrounded by the cell region 11 and the peripheral region 12.

The peripheral region 12 includes two gate fingers 23A and 23B, an emitter extension 24, a field limiting ring (FLR) portion 25, and an equipotential ring 26. The emitter electrode 21, the gate electrode 22, the gate fingers 23A and 23B, the emitter extension 24, the FLR portion 25, and the equipotential ring 26 include a common metal film. The metal film is formed from a material including, for example, AlCu (alloy of aluminum and copper).

When current is supplied to the gate electrode 22, the two gate fingers 23A and 23B are configured to quickly supply the current to cells in the emitter electrode 21 located distant from the gate electrode 22. The two gate fingers 23A and 23B are integrated with the gate electrode 22. The two gate fingers 23A and 23B are joined to one of opposite ends of the gate electrode 22 in the y-direction located closer to the device side surface 10c.

The gate finger 23A extends from the gate electrode 22 toward the device side surface 10a so as to surround the emitter electrode 21 from the device side surface 10c, the device side surface 10a, and the device side surface 10d. The gate finger 23B extends from the gate electrode 22 toward the device side surface 10b so as to surround the emitter electrode 21 from the device side surface 10c, the device side surface 10b, and the device side surface 10d. The distal end of the gate finger 23A and the distal end of the gate finger 23B are spaced apart and opposed to each other in the x-direction at a location closer to the device side surface 10d than the emitter electrode 21.

The emitter extension 24 is integrated with the emitter electrode 21 and is looped to surround the two gate fingers 23A and 23B.

The FLR portion 25 includes a termination structure that improves the dielectric strength of the semiconductor device 10 and is arranged at an outer side of the emitter extension 24. The FLR portion 25 is looped to surround the emitter electrode 21 and the gate electrode 22. In the present embodiment, the FLR portion 25 has the form of a closed loop. The FLR portion 25 reduces the electric field in the peripheral region 12 and limits the effects of external ions, thereby improving the dielectric strength of the semiconductor device 10.

The equipotential ring 26 has a termination structure that improves the dielectric strength of the semiconductor device 10 and is looped to surround the FLR portion 25. As shown in FIG. 1, the equipotential ring 26 is arranged on an outermost peripheral portion of the device main surface 10s. In the present embodiment, the equipotential ring 26 has the form of a closed loop. The equipotential ring 26 improves the dielectric strength of the semiconductor device 10.

As shown in FIG. 1, the semiconductor device 10 includes a passivation film 13 covering the emitter electrode 21, the gate electrode 22, the two gate fingers 23A and 23B, the emitter extension 24, the FLR portion 25, and the equipotential ring 26. The passivation film 13 is a protection film that protects the semiconductor device 10 from the outside of the semiconductor device 10. The passivation film 13 is an organic insulation film formed from a material including, for example, polyimide (PI).

The passivation film 13 includes a first opening 14 and a second opening 15. The first opening 14 exposes a portion of the emitter electrode 21. This forms an emitter electrode pad 16. The second opening 15 exposes a large portion of the gate electrode 22. This forms a gate electrode pad 17. As described above, the openings 14 and 15 form pads configured to be bonded to a conductive member (not shown) from the outside of the semiconductor device 10.

FIG. 3 is a diagram showing an example of the cross-sectional structure of a portion of the cell region 11. For the sake of convenience, FIG. 3 does not show hatching of some components of the semiconductor device 10 in the cell region 11.

As shown in FIG. 3, the semiconductor device 10 includes a semiconductor substrate 30. The semiconductor substrate 30 is formed from, for example, a material containing n⁻-type silicon (Si). The semiconductor substrate 30 has a thickness that is, for example, greater than or equal to 50 μm and less than or equal to 200 μm.

The semiconductor substrate 30 includes a substrate front surface 30s and a substrate back surface 30r that face opposite directions in the z-direction. Thus, the z-direction may be also referred to as the thickness-wise direction of the semiconductor substrate 30. Hence, “viewed in the z-direction” may be referred to as “viewed in the thickness-wise direction of the semiconductor substrate 30”.

The semiconductor substrate 30 has a structure in which a p⁺-type collector layer 31, an n⁻-type buffer layer 32, and an n-type drift layer 33 are stacked in this order from the substrate back surface 30r toward the substrate front surface 30s. A collector electrode 29 is formed on the substrate back surface 30r. The collector electrode 29 is formed on substantially the entirety of the substrate back surface 30r. The surface of the collector electrode 29 opposite to the substrate back surface 30r defines the device back surface 10r of the semiconductor device 10. In the present embodiment, the drift layer 33 corresponds to a “first semiconductor layer of a first conductive type.”

In an example, boron (B), aluminum (Al), or the like is used as the p-type dopant in the collector layer 31. The concentration of the dopant in the collector layer 31 is, for example, greater than or equal to 1×10¹⁵ cm⁻³ and less than or equal to 2×10¹⁹ cm⁻³.

In an example, nitrogen (N), phosphorus (P), arsenic (As), or the like is used as the n-type dopant in the buffer layer 32 and drift layer 33. The concentration of the dopant in the buffer layer 32 is, for example, greater than or equal to 1×10¹¹ cm⁻³ and less than or equal to 5×10¹⁷ cm⁻³. The concentration of the dopant in the drift layer 33 is lower than that of the buffer layer 32 and is, for example, greater than or equal to 1×10¹³ cm⁻³ and less than or equal to 5×10¹⁴ cm⁻³.

A p-type base region 34 is formed on the surface of the drift layer 33, that is, on the substrate front surface 30s. The base region 34 is formed on substantially the entirety of the substrate front surface 30s. The concentration of the dopant in the base region 34 is, for example, greater than or equal to 1×10¹⁶ cm⁻³ and less than or equal to 1×10¹⁸ cm⁻³. The depth of the base region 34 from the substrate front surface 30s is, for example, greater than or equal to 1.0 μm and less than or equal to 4.0 μm. In the present embodiment, the z-direction conforms to the thickness-wise direction of the drift layer 33. Hence, “viewed in the z-direction” may be referred to as “viewed in the thickness-wise direction of the drift layer 33.” Since the drift layer 33 corresponds to the first semiconductor layer, “viewed in the z-direction” may be also referred to as “viewed from the first semiconductor layer.”

Trenches 35 are arranged next to each other on the surface of the base region 34 (substrate front surface 30s) in the cell region 11. In an example, the trenches 35 extend in the y-direction and are spaced apart from each other in the x-direction. This forms stripes of the main cells 11A. The interval of the trenches 35 located adjacent to each other in the x-direction (center-to-center distance between the trenches 35) is, for example, greater than or equal to 1.5 μm and less than or equal to 7.0 μm. The width of each trench 35 (the dimension of the trench 35 in the x-direction) is, for example, greater than or equal to 0.5 μm and less than or equal to 3.0 μm. Each trench 35 extends through the base region 34 in the z-direction to an intermediate portion of the drift layer 33. The trenches 35 may have the form of a grid to separate the main cells 11A arranged in a matrix.

N⁺-type emitter regions 36 are formed on the surface of the base region 34 (substrate front surface 30s) in the cell region 11. The emitter regions 36 are disposed at opposite sides of the trench 35 in the x-direction. In other words, the emitter regions 36 are arranged in the base region 34 at opposite sides of each trench 35 in the arrangement direction of the trenches 35. Thus, two emitter regions 36 are spaced apart from each other in the x-direction and arranged between the trenches 35 located adjacent to each other in the x-direction. The depth of each emitter region 36 is, for example, greater than or equal to 0.2 m and less than or equal to 0.6 μm. The concentration of the dopant in the emitter regions 36 is higher than that of the base region 34 and is, for example, greater than or equal to 1×10¹⁹ cm⁻³ and less than or equal to 5×10²⁰ cm⁻³.

P⁺-type base contact regions 37 are formed on the surface of the base region 34 (substrate front surface 30s) in the cell region 11. The base contact regions 37 are arranged adjacent to the emitter regions 36 in the x-direction. That is, each base contact region 37 is arranged, in the x-direction, between the two emitter regions 36 arranged between the trenches 35 located adjacent to each other in the x-direction. The base contact region 37 may be formed to be deeper than the emitter region 36. The depth of the base contact region 37 is, for example, greater than or equal to 0.2 μm and less than or equal to 0.8 μm. The concentration of the dopant in the base contact region 37 is higher than that of the base region 34 and, for example, greater than or equal to 5×10¹⁸ cm⁻³ and less than or equal to 1×10²⁰ cm⁻³.

An insulation film 38 is integrally formed on the wall surface of each trench 35 and the substrate front surface 30s. In other words, the insulation film 38 is formed on the surface of the drift layer 33. The insulation film 38 includes, for example, silicon oxide (SiO₂). The thickness of the insulation film 38 is, for example, greater than or equal to 1100 angstroms and less than or equal to 1300 angstroms. In other words, the insulation film 38 in the cell region 11 forms a gate insulation film.

An electrode material formed from, for example, polysilicon, is embedded in each trench 35 with the insulation film 38. The electrode material embedded in each trench 35 is electrically connected to one of the gate electrode 22 (gate fingers 23A and 23B) or the emitter electrode 21. In other words, the conductive material embedded in the trenches 35 forms a gate trench 22A or an emitter trench 21A. In the present embodiment, the gate trenches 22A and the emitter trenches 21A are alternately arranged in the arrangement direction of the trenches 35. In the present embodiment, each of the gate trenches 22A and the emitter trenches 21A fills the trench 35 to the opening end of the trench 35.

An intermediate insulation film 39 is formed on a surface 38s of the insulation film 38 arranged on the substrate front surface 30s. The intermediate insulation film 39 includes, for example, SiO₂. The intermediate insulation film 39 is greater in thickness than the insulation film 38 and has a thickness of, for example, greater than or equal to 3000 angstroms and less than or equal to 15000 angstroms.

A barrier layer 40 is formed on a surface 39s of the intermediate insulation film 39. The barrier layer 40 limits entrance of external ions from the passivation film 13 into the substrate front surface 30s of the semiconductor substrate 30. More specifically, the barrier layer 40 includes a material having a smaller diffusion coefficient of an external ion than that of the passivation film 13. In the present embodiment, the barrier layer 40 includes a material having a smaller diffusion coefficient of an external ion than that of the intermediate insulation film 39. The barrier layer 40 also includes a material having a smaller diffusion coefficient of an external ion than that of the insulation film 38. Therefore, the barrier layer 40 includes a material having a smaller diffusion coefficient of an external ion than that of each of the passivation film 13, the intermediate insulation film 39, and the insulation film 38. The barrier layer 40 is formed from a material, for example, including silicon nitride. In the present embodiment, the barrier layer 40 includes SiN as a silicon nitride. The thickness of the barrier layer 40 is less than the thickness of the intermediate insulation film 39. The barrier layer 40 is shaped in conformance with the surface 39s of the intermediate insulation film 39.

The emitter electrode 21 is formed on the intermediate insulation film 39 and the barrier layer 40. Thus, the intermediate insulation film 39 and the barrier layer 40 are interlayer insulation films that fill the space between the emitter electrode 21 and the gate trench 22A and the space between the emitter electrode 21 and the emitter trench 21A. In other words, the barrier layer 40 is disposed between the intermediate insulation film 39 and the emitter electrode 21. The barrier layer 40 includes a front surface 40s and a back surface 40r. The front surface 40s is in contact with the emitter electrode 21. The back surface 40r is in contact with the surface 39s of the intermediate insulation film 39.

Openings 38a extend through the insulation film 38 in the z-direction. Each opening 38a is arranged to overlap the base contact region 37 as viewed in the z-direction.

The intermediate insulation film 39 includes openings 39a extending through the intermediate insulation film 39 in the z-direction. Each opening 39a is arranged to overlap the base contact region 37 as viewed in the z-direction.

The barrier layer 40 includes barrier layer openings 40a extending through the barrier layer 40 in the z-direction. Each barrier layer opening 40a is arranged to overlap the base contact region 37 as viewed in the z-direction.

In the present embodiment, the opening 39a is defined by a wall surface 39b, and the barrier layer opening 40a is defined by a wall surface 40b. The wall surface 39b is flush with the wall surface 40b. The emitter electrode 21 is connected to the base contact region 37 through the openings 39a and the barrier layer openings 40a.

Thus, the base contact region 37 is exposed through the openings 38a of the insulation film 38, the openings 39a of the intermediate insulation film 39, and the barrier layer openings 40a. The openings 38a, 39a, and 40a form contact holes that allow the emitter electrode 21 to contact the base contact region 37.

The emitter electrode 21 includes a plug electrode 21b embedded in each contact hole. The plug electrodes 21b include, for example, tungsten (W). In the present embodiment, the plug electrodes 21b are arranged so that distal ends of the plug electrodes 21b are embedded from the substrate front surface 30s of the semiconductor substrate 30. The emitter electrode 21 includes an electrode body 21c covering the plug electrodes 21b. The electrode body 21c is arranged on the plug electrodes 21b. The electrode body 21c projects upward beyond the intermediate insulation film 39 and the barrier layer 40. The electrode body 21c covers the barrier layer 40.

More specifically, the emitter electrode 21 includes a barrier metal layer 21e. The barrier metal layer 21e is formed on the front surface 40s of the barrier layer 40, the wall surface 39b defining the opening 39a, the wall surface 40b defining the barrier layer opening 40a, a wall surface 38b defining the opening 38a, and the surface (the substrate front surface 30s) of the drift layer 33 that is open through the openings 38a, 39a, and 40a. The barrier metal layer 21e is formed of, for example, a stacked structure of titanium (Ti) and titanium nitride (TiN). Thus, the barrier metal layer 21e includes portions of each plug electrode 21b that are in contact with the wall surfaces 38b, 39b, and 40b and the substrate front surface 30s and a portion of the electrode body 21c that is in contact with the front surface 40s of the barrier layer 40.

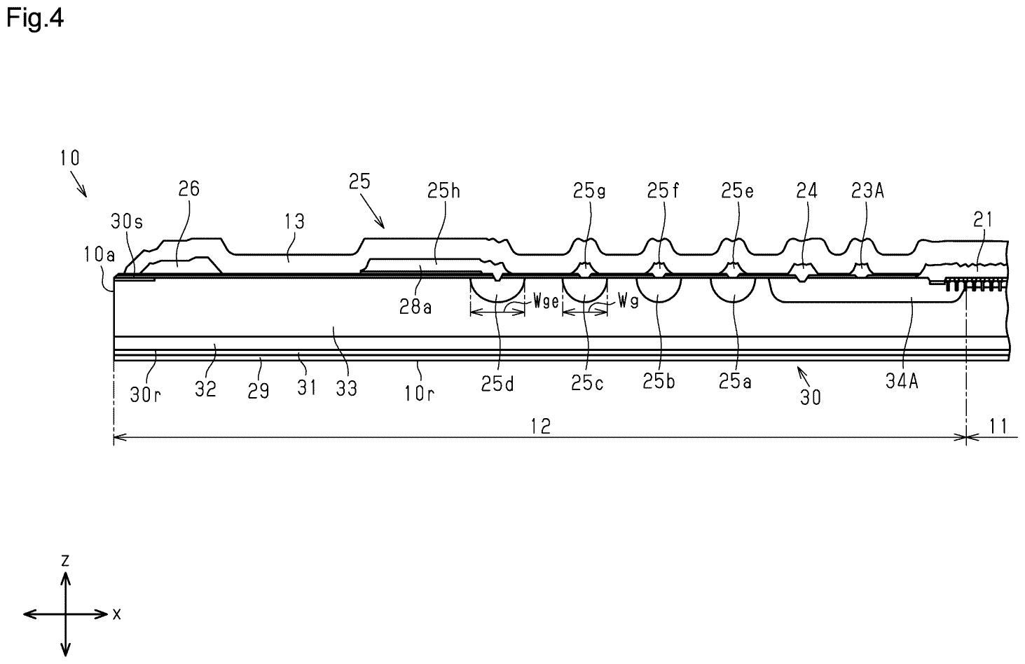

The structure of the peripheral region 12 will be described in detail with reference to FIGS. 4 to 7.

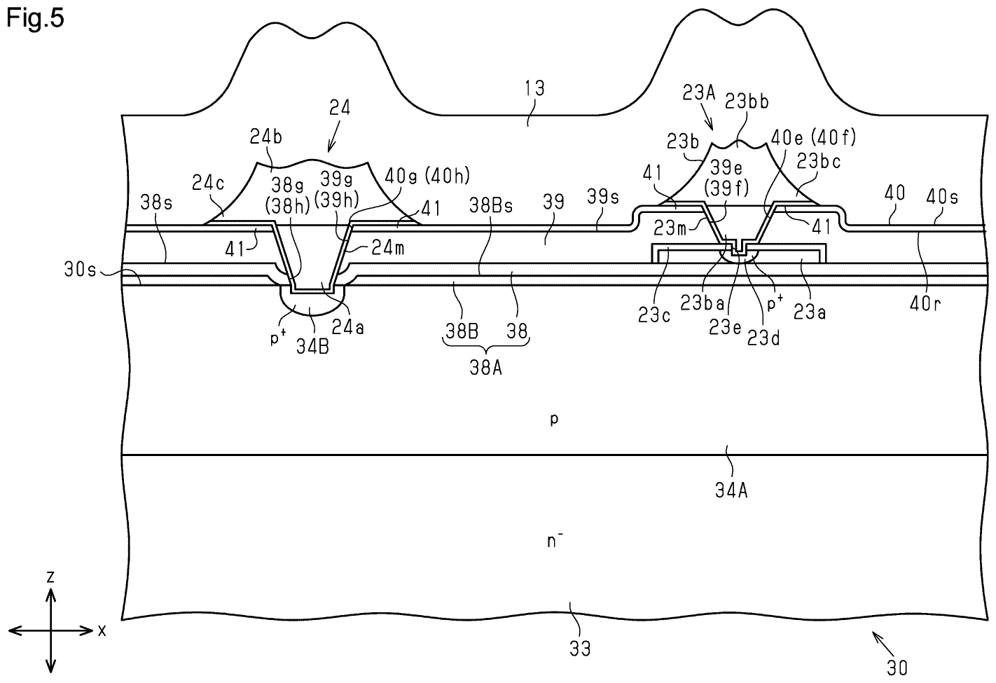

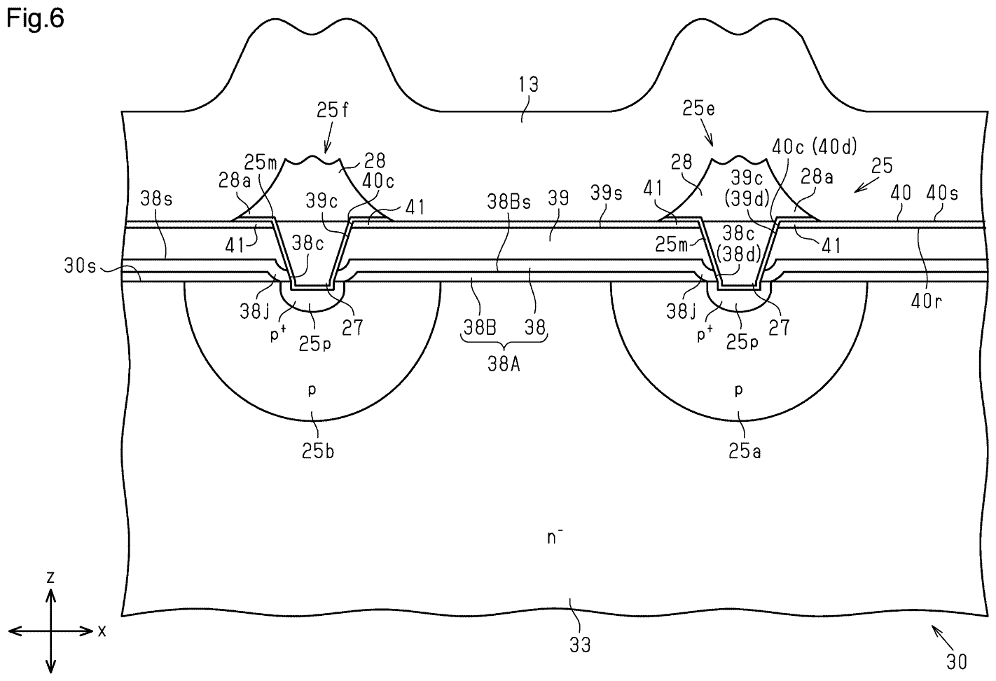

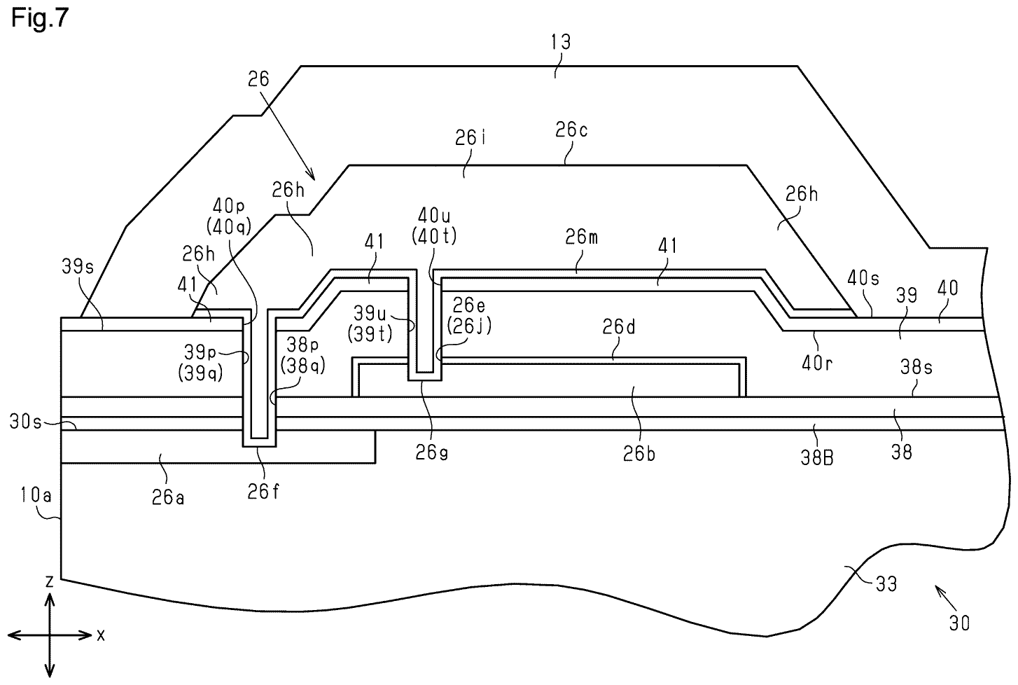

FIG. 4 is a diagram showing the cross-sectional structure of a portion of the peripheral region 12. FIG. 5 is an enlarged view showing the structure of the gate finger 23A and the emitter extension 24 of the peripheral region 12 shown in FIG. 4. FIG. 6 is an enlarged view showing the structure of the FLR portion 25 and its surroundings of the peripheral region 12 shown in FIG. 4. FIG. 7 is an enlarged view showing the structure of the equipotential ring 26 and its surroundings of the peripheral region 12 shown in FIG. 4. For the sake of convenience, FIGS. 4 to 7 do not show hatching of the components of the semiconductor device 10.

As shown in FIGS. 4 to 7, the drift layer 33 is formed in the peripheral region 12. In the peripheral region 12, the insulation film 38A and the intermediate insulation film 39 are formed on the substrate front surface 30s of the semiconductor substrate 30. Thus, the insulation film 38A and the intermediate insulation film 39 cover the surface of the drift layer 33 in the peripheral region 12. The insulation film 38A of the peripheral region 12 includes the insulation film 38 of the cell region 11. The insulation film 38A is formed separately from the insulation film 38. The barrier layer 40 is formed on the surface 39s of the intermediate insulation film 39 in the peripheral region 12 in the same manner as the cell region 11. In the present embodiment, the insulation film 38A corresponds to a “first insulation film.” The intermediate insulation film 39 corresponds to a “second insulation film.”

As shown in FIG. 6, the insulation film 38A includes a substrate-side insulation film 38B formed on the substrate front surface 30s of the semiconductor substrate 30 and the insulation film 38 that serves as a substrate-far-side insulation film formed on a surface 38Bs of the substrate-side insulation film 38B. Thus, in the present embodiment, the insulation film 38A has a two-layer stacked structure of the substrate-side insulation film 38B and the insulation film 38. The substrate-side insulation film 38B is an oxide film formed by thermally oxidizing the semiconductor substrate 30. Thus, the intermediate insulation film 39, which is formed on the insulation film 38A, is formed on the surface 38s of the insulation film 38.

As shown in FIG. 4, a p-type base region 34A is formed in a portion of the peripheral region 12 located adjacent to the cell region 11. The base region 34A is formed on the substrate front surface 30s of the semiconductor substrate 30 in the same manner as the base region 34. The base region 34A is partially formed on the drift layer 33. Thus, the surface of the base region 34A is covered by the insulation film 38A and the intermediate insulation film 39. In other words, the insulation film 38A and the intermediate insulation film 39 (refer to FIG. 5) cover the surface of the drift layer 33 and the surface of the base region 34A. The concentration of the dopant in the base region 34A is, for example, greater than or equal to 1×10¹⁶ cm⁻³ and less than or equal to 1×10¹⁸ cm⁻³.

The depth of the base region 34A in the peripheral region 12 is greater than that of the base region 34 (refer to FIG. 3) in the cell region 11. More specifically, the depth of the base region 34A in the peripheral region 12 is greater than that of the trench 35. In the present embodiment, the base region 34A extends to a position that overlaps with the peripheral portion of the emitter electrode 21 as viewed in the z-direction. Thus, the base region 34A is also formed on the peripheral portion of the cell region 11. The barrier layer 40 (refer to FIG. 5) is arranged to overlap the base region 34A as viewed in the z-direction. The barrier layer 40 covers the base region 34A as viewed in the z-direction. In the present embodiment, as viewed in the z-direction, the barrier layer 40 extends over an outer edge of the base region 34A. In the present embodiment, the base region 34A corresponds to a “second semiconductor region of a second conductive type.”

As shown in FIG. 4, the FLR portion 25 is formed at an outer side of the base region 34A. The FLR portion 25 includes multiple (in the present embodiment, four) looped conductors separated from each other and a semiconductor region.

Multiple (in the present embodiment, four) looped guard rings 25a to 25d are formed on the substrate front surface 30s of the semiconductor substrate 30. In the present embodiment, the guard rings 25a to 25d have the form of a closed loop. The guard rings 25a to 25d are partially formed in the drift layer 33. The guard rings 25a to 25d are semiconductor regions of the second conductive type (in the present embodiment, p-type) and are separated from each other in a direction orthogonal to the z-direction. The guard rings 25a to 25d are arranged in the order of the guard ring 25a, the guard ring 25b, the guard ring 25c, and the guard ring 25d in a direction away from the emitter electrode 21. The outermost guard ring 25d has a width Wge that is greater than a width Wg of the guard rings 25a to 25c. Examples of a p-type dopant in the guard rings 25a to 25d include B and Al. The concentration of the dopant in the guard rings 25a to 25d is, for example, equal to that of the base region 34A and greater than or equal to 1×10¹⁶ cm⁻³ and 1×10¹⁸ cm⁻³. In this case, the guard rings 25a to 25d and the base region 34A may be formed in the same step. In the present embodiment, the guard rings 25a to 25d correspond to a “second semiconductor region of a second conductive type.” The width Wge of the guard ring 25d may be changed in any manner. In an example, the width Wge of the guard ring 25d may be equal to the width Wg of the guard rings 25a to 25c.

The FLR portion 25 includes field plates 25e to 25h arranged in correspondence with the guard rings 25a to 25d. A viewed in the z-direction, the field plate 25e is arranged to overlap the guard ring 25a. The field plate 25f is arranged to overlap the guard ring 25b. The field plate 25g is arranged to overlap the guard ring 25c. The field plate 25h is arranged to overlap the guard ring 25d. The field plate 25e is in contact with the guard ring 25a. The field plate 25f is in contact with the guard ring 25b. The field plate 25g is in contact with the guard ring 25c. The field plate 25h is in contact with the guard ring 25d. In the present embodiment, the field plates 25e to 25h correspond to an “electrode.”

FIG. 6 shows an enlarged view of the FLR portion 25 showing the guard rings 25a and 25b, the field plates 25e and 25f, and their surroundings. The structure of the guard ring 25a and the field plate 25e is the same as that of the guard rings 25b and 25c and the field plates 25f and 25g. The structure of the guard ring 25d and the field plate 25h is also the same as that of the guard ring 25a and the field plate 25e except that the field plate 25h extends outward. Hence, the structure of the guard ring 25a and the field plate 25e will be described, and the structure of the guard rings 25b to 25d and the field plates 25f to 25h will not be described.

A barrier layer opening 40c and openings 39c and 38c are formed in the barrier layer 40, the intermediate insulation film 39, and the insulation film 38A at a position overlapping the guard ring 25a as viewed in the z-direction. The barrier layer opening 40c extends through the barrier layer 40 in the z-direction. The opening 39c extends through the intermediate insulation film 39 in the z-direction. The opening 38c extends through the insulation film 38A in the z-direction. The barrier layer opening 40c, the opening 39c, and the opening 38c are continuous with each other. As viewed in the z-direction, the area of opening of each of the barrier layer opening 40c, the opening 39c, and the opening 38c is smaller than the area of the surface of the guard ring 25a. The openings 40c, 39c, and 38c form a contact hole that exposes a portion of the surface of the guard ring 25a and allows the guard ring 25a to contact the field plate 25e. The barrier layer opening 40c is defined by a wall surface 40d. The opening 39c is defined by a wall surface 39d. The opening 38c is defined by a wall surface 38d. The wall surfaces 40d, 39d, and 38d are flush with each other.

As shown in FIG. 6, a portion of the insulation film 38A defining the opening 38c is inclined toward the drift layer 33 as the wall surface 38d of the opening 38c becomes closer. In the present embodiment, the insulation film 38A has an opening end including a curved portion 38j. The curved portion 38j is curved toward the drift layer 33 as the center of the opening 38c becomes closer. The intermediate insulation film 39 covers the curved portion 38j.

The field plate 25e is arranged in the barrier layer opening 40c and the openings 39c and 38c and is in contact with the guard ring 25a.

The field plate 25e includes a first part 27 arranged in the openings 39c and 38c and a second part 28 including a projection 28a projecting sideward from the first part 27 and overlapping with the intermediate insulation film 39. In the present embodiment, the first part 27 and the second part 28 are separately provided. The first part 27 includes, for example, tungsten (W). The second part 28 includes, for example, AlCu. In other words, the first part 27 is arranged in the barrier layer opening 40c. The projection 28a is located in the guard ring 25a as viewed in the z-direction.

The second part 28 is arranged on the first part 27. The second part 28 projects away from the drift layer 33 with respect to the intermediate insulation film 39. That is, the second part 28 projects upward from the intermediate insulation film 39. The projection 28a defines ends of the second part 28. More specifically, as viewed in the z-direction, the projection 28a defines opposite ends in a direction orthogonal to the direction in which the field plate 25e extends, that is, opposite ends in the width-wise direction of the field plate 25e. The second part 28 is curved and inclined toward the surface 39s of the intermediate insulation film 39 as the second part 28 extends outward in the width-wise direction of the field plate 25e. The second part 28 is formed by wet-etching. Thus, the shape of the second part 28 is obtained by wet-etching.

The first part 27 includes a lower end embedded in an upper portion of the guard ring 25a. In the guard ring 25a, a p⁺-type contact region 25p is formed in a portion corresponding to the first part 27. Examples of a p-type dopant in the contact region 25p include B and Al. The concentration of the dopant in the contact region 25p is greater than that in the guard ring 25a and, for example, greater than or equal to 5×10¹⁸ cm⁻³ and less than or equal to 1×10²⁰ cm⁻³.

The field plate 25e includes a barrier metal layer 25m. The barrier metal layer 25m is formed on the front surface 40s of the barrier layer 40, the wall surface 39d defining the opening 39c, the wall surface 40d defining the barrier layer opening 40c, the wall surface 38d defining the opening 38c, and the surface (the substrate front surface 30s) of the drift layer 33 that is open through the openings 38c, 39c, and 40c. The barrier metal layer 25m is formed of, for example, a stacked structure of Ti and TiN. Thus, the barrier metal layer 25m includes portions of the first part 27 that are in contact with the wall surfaces 38d, 39d, and 40d, the surface of the drift layer 33 described above, and a portion of the second part 28 that is in contact with the front surface 40s of the barrier layer 40.

The barrier layer 40 includes an intermediate portion 41 arranged between the projection 28a of the field plate 25e and the guard ring 25a. In the present embodiment, the intermediate portion 41 is sandwiched between the projection 28a of the field plate 25e and the intermediate insulation film 39. In other words, the barrier layer 40 includes a portion (intermediate portion 41) sandwiched between the projection 28a of the field plate 25e and the intermediate insulation film 39. The intermediate portion 41 includes the barrier layer opening 40c, through which the first part 27 of the field plate 25e is inserted. Thus, as viewed in the z-direction, the intermediate portion 41 extends to the edge of the intermediate insulation film 39 defining the opening 39c, through which the first part 27 of the field plate 25e is inserted.

The barrier layer 40 extends inward from the contact hole of the guard ring 25a to the emitter extension 24 (refer to FIG. 5). The barrier layer 40 extends, for example, from the contact hole of the guard ring 25a to the contact hole of the guard ring 25b. The barrier layer 40 entirely covers the guard ring 25a as viewed in the z-direction. Further, the barrier layer 40 extends over an outer edge of the guard ring 25a as viewed in the z-direction.

As shown in FIG. 4, the field plate 25h has a projection 28a that extends in a direction away from the field plate 25g and is greater in length than the projection 28a of the field plate 25e. The projection 28a of the field plate 25h extending in a direction away from the field plate 25g extends over the guard ring 25d as viewed in the z-direction.

As shown in FIG. 4, as viewed in the z-direction, the gate finger 23A (23B) and the emitter extension 24 are arranged to overlap with the base region 34A. The gate finger 23A (23B) is separated outward from the emitter electrode 21.

As shown in FIG. 5, the gate finger 23A includes a gate layer 23a formed on the surface 38s of the insulation film 38 and a gate interconnect 23b formed on the front surface 40s of the barrier layer 40.

The gate layer 23a is formed from, for example, polysilicon so as to surround the emitter electrode 21 from the device side surface 10c, the device side surface 10a, and the device side surface 10d (refer to FIG. 1). The gate layer 23a is covered by the intermediate insulation film 39. An oxide film 23c is formed on a surface of the gate layer 23a.

The gate interconnect 23b is arranged to overlap the gate layer 23a as viewed in the z-direction. The gate interconnect 23b is integrated with the gate electrode 22.

The barrier layer 40, the intermediate insulation film 39, and the oxide film 23 respectively include a barrier layer opening 40e and openings 39e and 23e at a position corresponding to the gate finger 23A. The barrier layer opening 40e extends through the barrier layer 40 in the z-direction. The opening 39e extends through the intermediate insulation film 39 in the z-direction. The opening 23e extends through the oxide film 23c in the z-direction. The barrier layer opening 40e and the openings 39e and 23e are continuous with each other. Thus, the gate layer 23a is exposed through the barrier layer opening 40e and the openings 39e and 23e. The gate interconnect 23b is arranged in the barrier layer opening 40e and the openings 39e and 23e and is in contact with the gate layer 23a. The barrier layer opening 40e and the openings 39e and 23e form a contact hole that allows the gate interconnect 23b to contact the gate layer 23a. The barrier layer opening 40e is defined by a wall surface 40f. The opening 39e is defined by a wall surface 39f. The wall surface 40f is flush with the wall surface 39f.

The gate interconnect 23b includes a first part 23ba arranged in the opening 39e and a second part 23bb including a projection 23bc extending sideward from the first part 23ba and overlapping with the intermediate insulation film 39. In the present embodiment, the first part 23ba and the second part 23bb are separately provided. The first part 23ba is formed from, for example, tungsten (W). The second part 23bb includes, for example, AlCu. In other words, the first part 23ba is arranged in the barrier layer opening 40e.

The first part 23ba is arranged to overlap with the gate layer 23a and the gate interconnect 23b as viewed in the z-direction. The first part 23ba extends through the intermediate insulation film 39, located on the gate layer 23a, and the barrier layer 40, located on the intermediate insulation film 39, in the z-direction. In the present embodiment, the first part 23ba is embedded in an upper portion of the gate layer 23a.

A contact region 23d, which is a semiconductor region of p⁺-type, is formed in a portion of the gate layer 23a in which the first part 23ba is embedded. Examples of a p-type dopant in the contact region 23d include B and Al. The concentration of the dopant in the contact region 23d is greater than that in the base region 34A and is, for example, greater than or equal to 5×10¹⁸ cm⁻³ and less than or equal to 1×10²⁰ cm⁻³.

The second part 23bb is arranged on the first part 23ba. The second part 23bb projects away from the base region 34A with respect to the intermediate insulation film 39. That is, the second part 23bb projects upward from the intermediate insulation film 39. The projection 23bc defines ends of the second part 23bb. More specifically, as viewed in the z-direction, the projection 23bc defines opposite ends in a direction orthogonal to the direction in which the gate interconnect 23b extends, that is, opposite ends in the width-wise direction of the gate interconnect 23b. The second part 23bb is curved and inclined toward the surface 39s of the intermediate insulation film 39 as the second part 23bb extends outward in the width-wise direction of the gate interconnect 23b. The second part 23bb is formed by wet-etching. Thus, the shape of the second part 23bb is obtained by wet-etching.

The gate interconnect 23b includes a barrier metal layer 23m. The barrier metal layer 23m is formed on the front surface 40s of the barrier layer 40, the wall surface 39f defining the opening 39e, the wall surface 40f defining the barrier layer opening 40e, the wall surface defining the opening 23e, and the surface of the gate layer 23a that is open through the openings 23e, 39e, and 40e. The barrier metal layer 23m is formed of, for example, a stacked structure of Ti and TiN. Thus, the barrier metal layer 23m includes portions of the first part 23ba that are in contact with the wall surfaces 39f and 40f, the surface of the gate layer 23a described above, and a portion of the second part 23bb that is in contact with the front surface 40s of the barrier layer 40.

The barrier layer 40 includes an intermediate portion 41 arranged between the projection 23bc of the gate interconnect 23b and the base region 34A. In the present embodiment, the intermediate portion 41 is sandwiched between the projection 23bc of the gate interconnect 23b and the intermediate insulation film 39. In other words, the barrier layer 40 includes a portion (the intermediate portion 41) sandwiched between the projection 23bc of the gate interconnect 23b and the intermediate insulation film 39. The intermediate portion 41 includes the barrier layer opening 40e, through which the first part 23ba of the gate interconnect 23b is inserted. Thus, as viewed in the z-direction, the intermediate portion 41 extends to the edge of the intermediate insulation film 39 defining the opening 39e, through which the first part 23ba of the gate interconnect 23b is inserted.

The emitter extension 24 is formed of a metal film and is formed on the front surface 40s of the barrier layer 40. The emitter extension 24 is formed on the peripheral portion of the base region 34A.

The barrier layer 40, the intermediate insulation film 39, and the insulation film 38 respectively include a barrier layer opening 40g, an opening 39g, and an opening 38g at a position corresponding to the emitter extension 24. The barrier layer opening 40g extends through the barrier layer 40 in the z-direction. The opening 39g extends through the intermediate insulation film 39 in the z-direction. The opening 38g extends through the insulation film 38 in the z-direction. The barrier layer opening 40g and the openings 39g and 38g are continuous with each other. Thus, the base region 34A is exposed through the barrier layer opening 40g and the openings 39g and 38g. The emitter extension 24 is arranged in the barrier layer opening 40g and the openings 39g and 38g and is in contact with the base region 34A. The barrier layer opening 40g and the openings 39g and 38g form a contact hole that allows the emitter extension 24 to contact the base region 34A. The barrier layer opening 40g is defined by a wall surface 40h. The opening 39g is defined by a wall surface 39h. The opening 38g is defined by a wall surface 38h. The wall surfaces 40h, 39h, and 38h are flush with each other.

The emitter extension 24 includes a first part 24a arranged in the openings 39c and 38c and a second part 24b including a projection 24c projecting sideward from the first part 24a and overlapping with the intermediate insulation film 39. In the present embodiment, the first part 24a and the second part 24b are separately provided. The first part 24a is formed from, for example, tungsten (W). The second part 24b includes, for example, AlCu. The projection 24c is located in the base region 34A as viewed in the z-direction.

The first part 24a includes a lower end embedded in an upper portion of the base region 34A. In the base region 34A, a p⁺-type contact region 34B is formed in a portion corresponding to the first part 24a. Examples of a p-type dopant in the contact region 34B include B and Al. The concentration of the dopant in the contact region 34B is greater than that in the base region 34A and is, for example, greater than or equal to 5×10¹⁸ cm⁻³ and less than or equal to 1×10²⁰ cm⁻³.

The second part 24b is arranged on the first part 24a. The second part 24b projects away from the base region 34A with respect to the intermediate insulation film 39. That is, the second part 24b projects upward from the intermediate insulation film 39. The projection 24c defines ends of the second part 24b. More specifically, as viewed in the z-direction, the projection 24c defines opposite ends in a direction orthogonal to the direction in which the emitter extension 24 extends, that is, opposite ends in the width-wise direction of the emitter extension 24. The second part 24b is curved and inclined toward the surface 39s of the intermediate insulation film 39 as the second part 24b extends outward in the width-wise direction of the emitter extension 24. The second part 24b is formed by wet-etching. Thus, the shape of the second part 24b is obtained by wet-etching.

The emitter extension 24 includes a barrier metal layer 24m. The barrier metal layer 24m is formed on the front surface 40s of the barrier layer 40, the wall surface 39h defining the opening 39g, the wall surface 40h defining the barrier layer opening 40g, the wall surface 38h defining the opening 38g, and the surface (the substrate front surface 30s) of the drift layer 33 that is open through the openings 38g, 39g, and 40g. The barrier metal layer 24m is formed of, for example, a stacked structure of Ti and TiN. Thus, the barrier metal layer 24m includes portions of the first part 24a that are in contact with the wall surfaces 38h, 39h, and 40h, the surface of the drift layer 33 described above, and a portion of the second part 24b that is in contact with the front surface 40s of the barrier layer 40.

The barrier layer 40 includes an intermediate portion 41 arranged between the projection 24c of the emitter extension 24 and the base region 34A. In the present embodiment, the intermediate portion 41 is sandwiched between the projection 24c and the intermediate insulation film 39. In other words, the barrier layer 40 includes a portion (the intermediate portion 41) sandwiched between the projection 24c and the intermediate insulation film 39. The intermediate portion 41 includes the barrier layer opening 40g, through which the first part 24a of the emitter extension 24 is inserted. Thus, as viewed in the z-direction, the intermediate portion 41 extends to the edge of the intermediate insulation film 39 defining the opening 39g, through which the first part 24a of the emitter extension 24 is inserted.

As shown in FIG. 4, the equipotential ring 26 is formed at an outer side of the FLR portion 25. The insulation film 38 and the intermediate insulation film 39 are also formed in a region where the equipotential ring 26 is formed.

As shown in FIG. 7, the equipotential ring 26 includes a channel stop region 26a of a first conductive type (n⁺-type) formed on the surface (the substrate front surface 30s) of the drift layer 33, an inner interconnect 26b arranged in the insulation film 38 and the intermediate insulation film 39, and an outer interconnect 26c arranged on the front surface 40s of the barrier layer 40.

The channel stop region 26a extends from a position overlapping with the outer interconnect 26c to the device side surface 10a as viewed in the z-direction. The channel stop region 26a is located outward (toward the device side surface 10a) from the inner interconnect 26b. The concentration of the dopant in the channel stop region 26a is, for example, equal to that in the emitter region 36 (refer to FIG. 3) and is greater than or equal to 1×10¹⁹ cm⁻³ and less than or equal to 5×10²⁰ cm⁻³. In this case, in an example, the channel stop region 26a and the emitter region 36 are formed in the same step.

The inner interconnect 26b is arranged on the surface 38s of the insulation film 38 and covered by the intermediate insulation film 39. Since the intermediate insulation film 39 is covered by the barrier layer 40, the inner interconnect 26b is covered by the barrier layer 40. The inner interconnect 26b is formed from an electrode material such as polysilicon. The inner interconnect 26b is formed in the same step as the gate layer 23a (refer to FIG. 5) of the gate finger 23A. An oxide film 26d is formed on a surface of the inner interconnect 26b.

The barrier layer 40, the intermediate insulation film 39, and the oxide film 23c respectively include a barrier layer opening 40p and openings 39p and 38p at a position corresponding to the channel stop region 26a. The barrier layer opening 40p extends through the barrier layer 40 in the z-direction. The opening 39p extends through the intermediate insulation film 39 in the z-direction. The opening 38p extends through the insulation film 38 in the z-direction. The barrier layer opening 40p and the openings 39p and 38p are continuous with each other. Thus, the channel stop region 26a is exposed through the barrier layer opening 40p and the openings 39p and 38p. The outer interconnect 26c is arranged in the barrier layer opening 40p and the openings 39p and 38p and is in contact with the channel stop region 26a. The barrier layer opening 40p and the openings 39p and 38p form a contact hole that allows the outer interconnect 26c to contact the channel stop region 26a. The barrier layer opening 40p is defined by a wall surface 40q. The opening 39p is defined by a wall surface 39q. The opening 38p is defined by a wall surface 39q. The wall surfaces 40q, 39q, and 39q are flush with each other.

The barrier layer 40, the intermediate insulation film 39, and the oxide film 26d respectively include a barrier layer opening 40u and openings 39u and 26e at a position corresponding to the inner interconnect 26b. The barrier layer opening 40u extends through the barrier layer 40 in the z-direction. The opening 39u extends through the intermediate insulation film 39 in the z-direction. The opening 26e extends through the oxide film 26d in the z-direction. The barrier layer opening 40u and the openings 39u and 26e are continuous with each other. Thus, the inner interconnect 26b is exposed through the barrier layer opening 40u and the openings 39u and 26e. The outer interconnect 26c is arranged in the barrier layer opening 40u and the openings 39u and 26e and is in contact with the inner interconnect 26b. The barrier layer opening 40u and the openings 39u and 26e form a contact hole that allows the outer interconnect 26c to contact the inner interconnect 26b. The barrier layer opening 40u is defined by a wall surface 40t. The opening 39u is defined by a wall surface 39t. The wall surface 40t is flush with the wall surface 39t.

The outer interconnect 26c includes two first parts 26f and 26g and a second part 26i including a projection 26h projecting sideward from the first parts 26f and 26g and overlapping with the intermediate insulation film 39. In the present embodiment, the first parts 26f and 26g and the second part 26i are separately provided. The first parts 26f and 26g are formed from a material including, for example, tungsten (W). The second part 26i is formed from a material including, for example, AlCu. The first part 26f is in contact with the channel stop region 26a. The first part 26g is in contact with the inner interconnect 26b. In other words, the first part 26f is arranged in the barrier layer opening 40p. The first part 26g is arranged in the barrier layer opening 40u.

The first part 26f is arranged to overlap with the channel stop region 26a and the outer interconnect 26c as viewed in the z-direction. The first part 26f extends through the insulation films 38 and 38B disposed on the channel stop region 26a, the intermediate insulation film 39 disposed on the insulation film 38, and the barrier layer 40 disposed on the intermediate insulation film 39 in the z-direction.

The first part 26g is arranged to overlap with the inner interconnect 26b and the second part 26i as viewed in the z-direction. The first part 26g is located inward from the first part 26f. The first part 26g extends through the oxide film 26d and the intermediate insulation film 39, located on the inner interconnect 26b, and the barrier layer 40, located on the intermediate insulation film 39. In the present embodiment, the first part 26g is embedded in an upper portion of the inner interconnect 26b.

The second part 26i is arranged on the first parts 26f and 26g. The second part 26i projects away from the drift layer 33 with respect to the intermediate insulation film 39. That is, the second part 26i projects upward from the intermediate insulation film 39. The projection 26h includes ends of the second part 26i and a portion of the second part 26i located between the first part 26f and the first part 26g as viewed in the z-direction. More specifically, as viewed in the z-direction, the projection 26h includes opposite ends in a direction orthogonal to the direction in which the outer interconnect 26c extends, that is, opposite ends in the width-wise direction of the outer interconnect 26c, and a portion located between the first part 26f and the first part 26g in a direction in which the outer interconnect 26c extends.

The outer interconnect 26c includes a barrier metal layer 26m. The barrier metal layer 26m is formed on the front surface 40s of the barrier layer 40, the wall surface 39q defining the opening 39p, the wall surface 40q defining the barrier layer opening 40p, the wall surface 38q defining the opening 38p, and the surface (the substrate front surface 30s) of the drift layer 33 that is open through the openings 38p, 39p, and 40p. The barrier metal layer 26m is also formed on the wall surface 39t defining the opening 39u, the wall surface 40t defining the barrier layer opening 40u, the wall surface 26j defining the opening 26e, and the surface of the inner interconnect 26b that is open through the openings 26e, 39u, and 40u. Thus, the barrier metal layer 26m includes portions of the first part 26f that are in contact with the wall surfaces 38q, 39q, and 40q and the surface of the channel stop region 26a. The barrier metal layer 26m also includes portions of the first part 26g that are in contact with the wall surfaces 26j, 39t, and 40t and the surface of the inner interconnect 26b. The barrier metal layer 26m also includes a portion of the second part 26i that is in contact with the front surface 40s of the barrier layer 40. The barrier metal layer 26m is formed of, for example, a stacked structure of Ti and TiN.

The barrier layer 40 includes an intermediate portion 41 arranged between the projection 26h of the outer interconnect 26c and the drift layer 33. In the present embodiment, the intermediate portion 41 is sandwiched between the projection 26h of the outer interconnect 26c and the intermediate insulation film 39. In other words, the barrier layer 40 includes a portion (the intermediate portion 41) sandwiched between the projection 26h of the outer interconnect 26c and the intermediate insulation film 39. The intermediate portion 41 includes the barrier layer openings 40p and 40u, through which the first parts 26f and 26g of the outer interconnect 26c are inserted. Thus, as viewed in the z-direction, the intermediate portion 41 extends to the edges of the intermediate insulation film 39 defining the openings 39p and 39u, through which the first parts 26f and 26g of the outer interconnect 26c are inserted.

As shown in FIGS. 4 to 7, the peripheral region 12 is covered by the passivation film 13. Thus, the barrier layer 40 is covered by the passivation film 13 as viewed in the z-direction. In the present embodiment, the barrier layer 40 is covered by the passivation film 13 in contact with the front surface 40s of the barrier layer 40 in a region in which the gate fingers 23A and 23B, the field plates 25e to 25h, and the equipotential ring 26 are not formed. That is, the barrier layer 40 is arranged between the passivation film 13 and the drift layer 33.

The passivation film 13 is arranged above the intermediate insulation film 39 and overlaps the intermediate insulation film 39 as viewed in the z-direction. More specifically, the passivation film 13 covers the intermediate insulation film 39.

Semiconductor Device Manufacturing Method

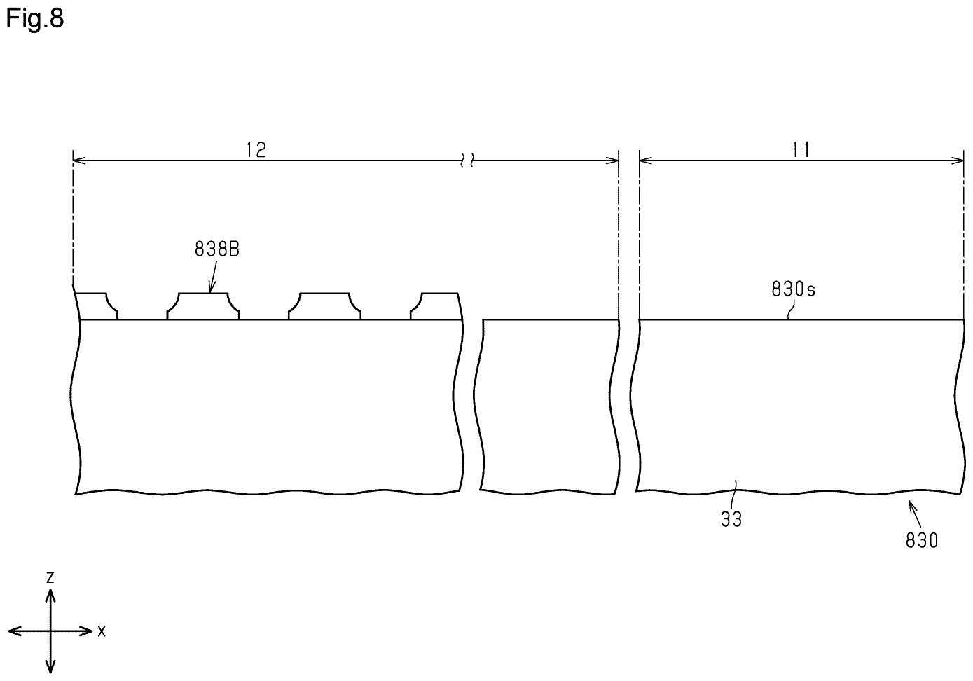

A method for manufacturing the semiconductor device 10 of the first embodiment will now be described with reference to FIGS. 8 to 20. In FIGS. 8 to 20, the structure of the semiconductor device 10 showing a manufacturing process is simplified for the sake of convenience. Hence, the components of the semiconductor device 10 shown in FIGS. 8 to 20 may differ in shape and size from the components of the semiconductor device 10 shown in FIGS. 1 to 4. FIGS. 8 to 20 show manufacturing processes of a portion of the cell region 11, the gate finger 23A, and a portion of the FLR portion 25. Hereafter, a method for manufacturing a single semiconductor device 10 will be described with reference to FIGS. 7 to 20 for the sake of convenience. The method for manufacturing the semiconductor device 10 of the present embodiment is not limited to manufacturing of a single semiconductor device 10 and may be manufacturing of a plurality of semiconductor devices 10.

The method for manufacturing the semiconductor device 10 of the present embodiment includes a step of preparing a semiconductor substrate 830 formed from a material including Si. The semiconductor substrate 830 includes an n⁻-type drift layer 33, corresponding to a semiconductor layer of a first conductive type. The drift layer 33 is entirely formed on the semiconductor substrate 830. The semiconductor substrate 830 includes a substrate front surface 830s and a substrate back surface (not shown) that face opposite directions in the thickness-wise direction (z-direction). Thus, the substrate front surface 830s is the surface of the drift layer 33. In the present embodiment, the step of preparing the semiconductor substrate 830 corresponds to “forming a first semiconductor layer of a first conductive type in a peripheral region.”

As shown in FIG. 8, the method for manufacturing the semiconductor device 10 of the present embodiment includes a step of forming a substrate-side insulation film 838B on a portion of the substrate front surface 830s of the semiconductor substrate 830 corresponding to the peripheral region 12. The substrate-side insulation film 838B is an insulation film corresponding to the substrate-side insulation film 38B of the semiconductor device 10.

The step of forming the substrate-side insulation film 838B includes a step of thermally oxidizing the semiconductor substrate 830 to form a first insulation layer on the substrate front surface 830s, a step of wet-etching the first insulation layer, and a step of dry-etching the first insulation layer.

More specifically, thermal oxidation of the semiconductor substrate 830 forms an oxide film on the entire surface of the semiconductor substrate 830. The oxide film is removed from the substrate front surface 830s of the semiconductor substrate 830 excluding the peripheral region 12. More specifically, the oxide film is wet-etched to reduce the thickness of the oxide film. In the peripheral region 12, a mask is used so that the thickness of the oxide film is partially reduced. Subsequently, the oxide film is removed by dry etching. In the peripheral region 12, the portion exposed by the mask is removed by dry etching. The steps described above form the substrate-side insulation film 838B on the substrate front surface 830s of the semiconductor substrate 830.

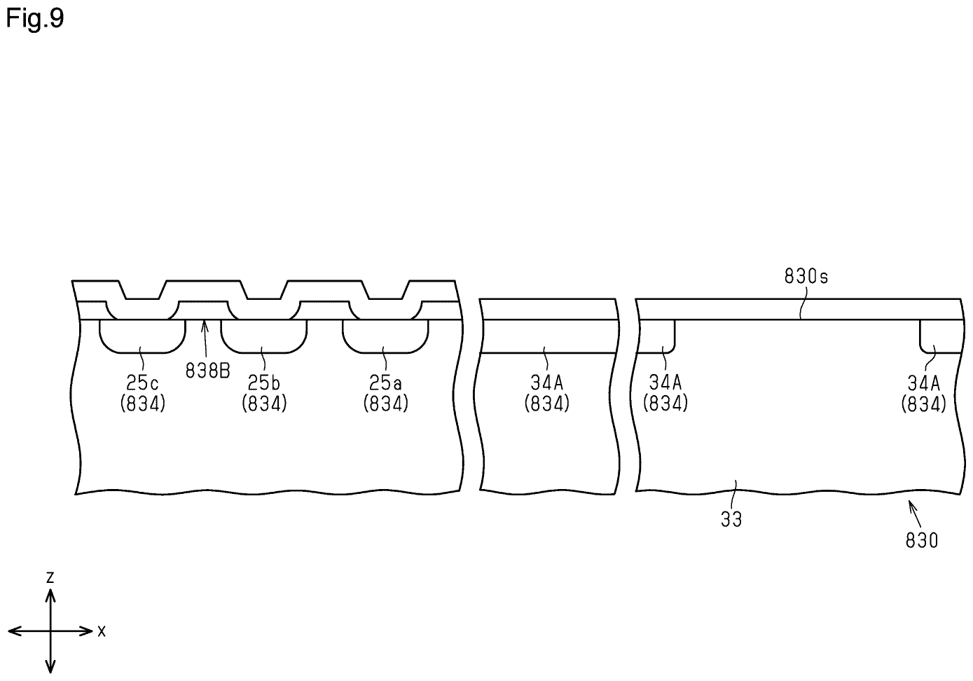

As shown in FIG. 9, the method for manufacturing the semiconductor device 10 of the present embodiment includes a step of forming a p-type well region 834, corresponding to a semiconductor region of a second conductive type, on the semiconductor substrate 830. More specifically, the substrate front surface 830s of the semiconductor substrate 830 is selectively doped with a p-type impurity. Subsequently, the semiconductor substrate 830 is heated so that the p-type impurity diffuses. The steps described above form the well region 834. The well region 834 is partially formed in the drift layer 33. The surface of the well region 834 defines the substrate front surface 830s and thus is continuous with the surface of the drift layer 33. The well region 834 includes the base region 34A and the guard rings 25a to 25d (the guard ring 25d is not shown in FIG. 9). The step of forming the well region 834 on the semiconductor substrate 830 corresponds to “partially forming a second semiconductor region of a second conductive type, including a surface continuous with a surface of the first semiconductor layer, on the first semiconductor layer.” Thus, the well region 834 is covered by the substrate-side insulation film 838B.

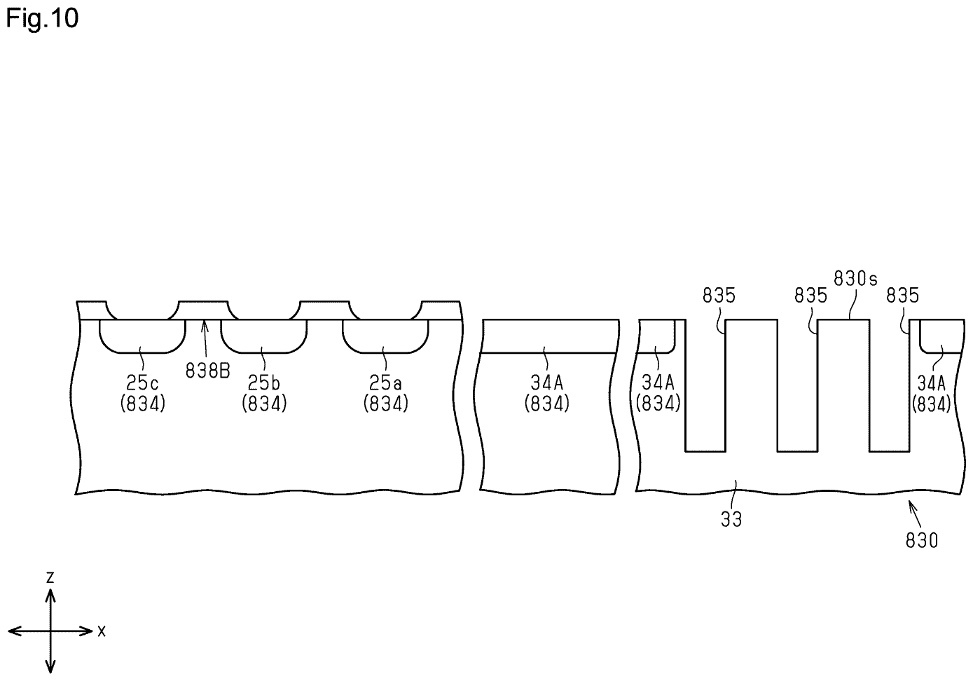

As shown in FIG. 10, the method for manufacturing the semiconductor device 10 of the present embodiment includes a step of forming trenches 835 in the semiconductor substrate 830. More specifically, a trench mask (not shown) is formed on the substrate front surface 830s of the semiconductor substrate 830. The trench mask is selectively etched. More specifically, as viewed in the z-direction, etching is performed on a region of the trench mask in which the trenches 835 will be formed. As a result, the trench mask exposes a region of the substrate front surface 830s of the semiconductor substrate 830 in which the trenches 835 will be formed. Etching is performed on the region of the substrate front surface 830s of the semiconductor substrate 830 in which the trenches 835 will be formed. As a result, the trenches 835 are formed in the semiconductor substrate 830.

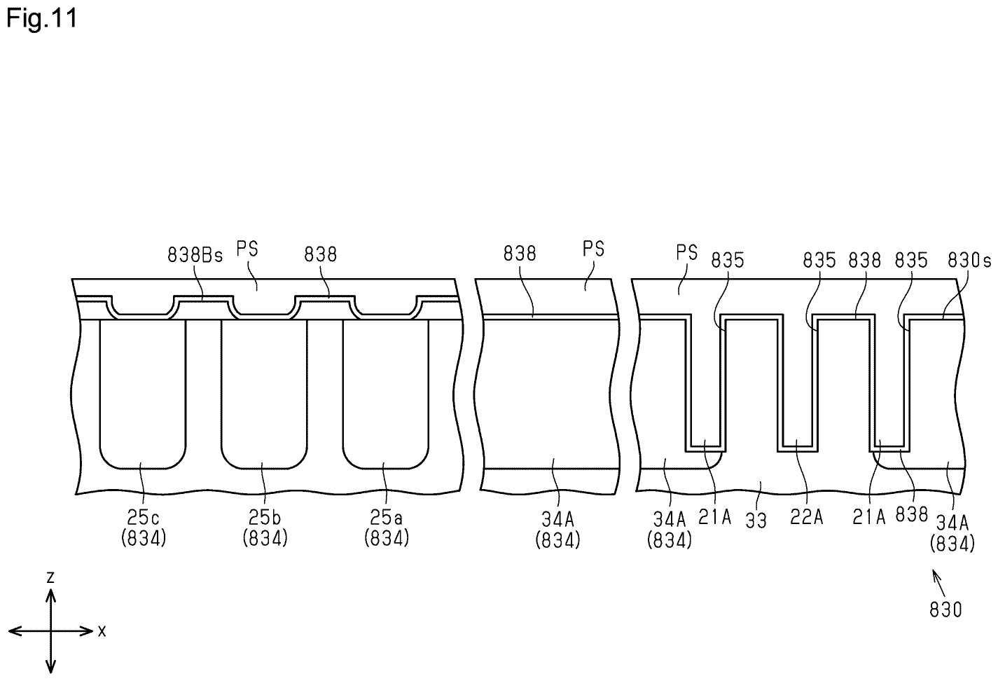

As shown in FIG. 11, the method for manufacturing the semiconductor device 10 of the present embodiment includes a step of forming an insulation film 838 and a step of forming an electrode.

In the step of forming the insulation film 838, the semiconductor substrate 830 is thermally oxidized to form an oxide film on the entire surface of the semiconductor substrate 830 including wall surfaces of the trenches 835. As a result, the insulation film 838 is formed on the substrate front surface 830s of the semiconductor substrate 830 in the cell region 11. The insulation film 838 corresponds to the insulation film 38. The insulation film 838 in the cell region 11 is a gate insulation film and is formed on the wall surface of each trench 835. In the peripheral region 12 of the semiconductor substrate 830, the insulation film 838 is formed on a surface 838Bs of the substrate-side insulation film 838B.

In the step of forming an electrode, an electrode material PS such as polysilicon is embedded in each trench 835 and also formed on the substrate front surface 830s of the semiconductor substrate 830. This forms the gate trenches 22A and the emitter trenches 21A.

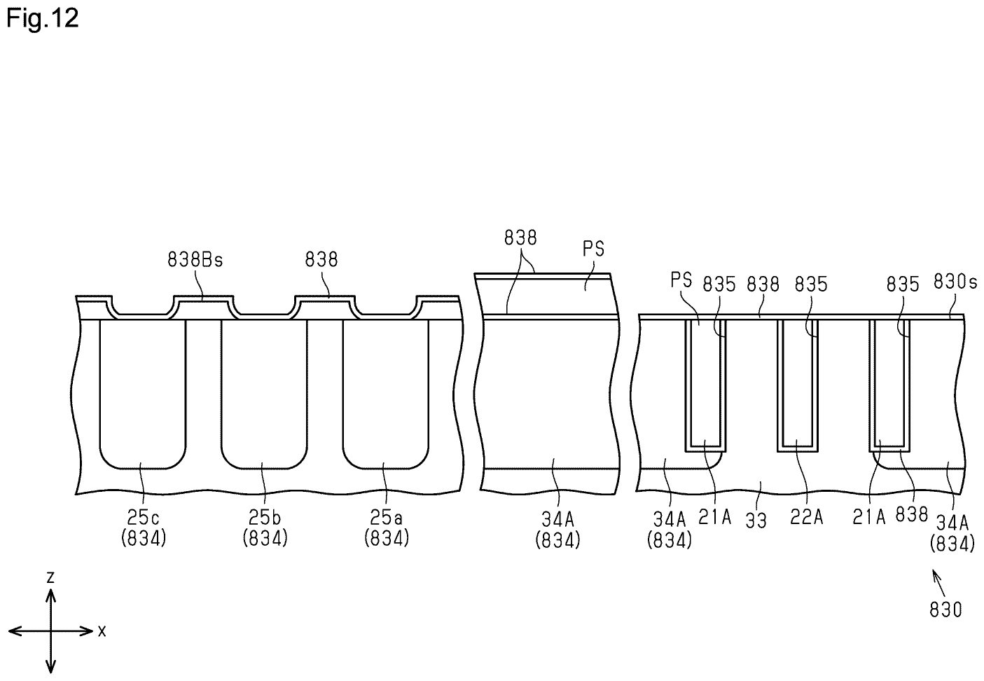

As shown in FIG. 12, the method for manufacturing the semiconductor device 10 of the present embodiment includes a step of etching the electrode material PS and a step of forming the insulation film 838 on the electrode material PS.

In the step of etching the electrode material PS, etching is performed to remove the electrode material PS from the substrate front surface 830s of the semiconductor substrate 830 in the cell region 11 and a portion of the peripheral region 12 excluding the gate fingers 23A and 23B, the gate electrode 22, and the inner interconnect 26b of the equipotential ring 26.

In the step of forming the insulation film 838 on the electrode material PS, the electrode material PS embedded in the trenches 835, the electrode material PS forming the gate fingers 23A and 23B and the gate electrode 22, and the electrode material PS forming the inner interconnect 26b of the equipotential ring 26 are oxidized. As a result, the insulation film 838 is formed on the electrode material PS. The electrode material PS of the gate fingers 23A and 23B is a part corresponding to the gate layer 23a. The insulation film 838 disposed on the electrode material PS is a film corresponding to the oxide film 23c of the gate fingers 23A and 23B and the oxide film 26d of the inner interconnect 26b of the equipotential ring 26.

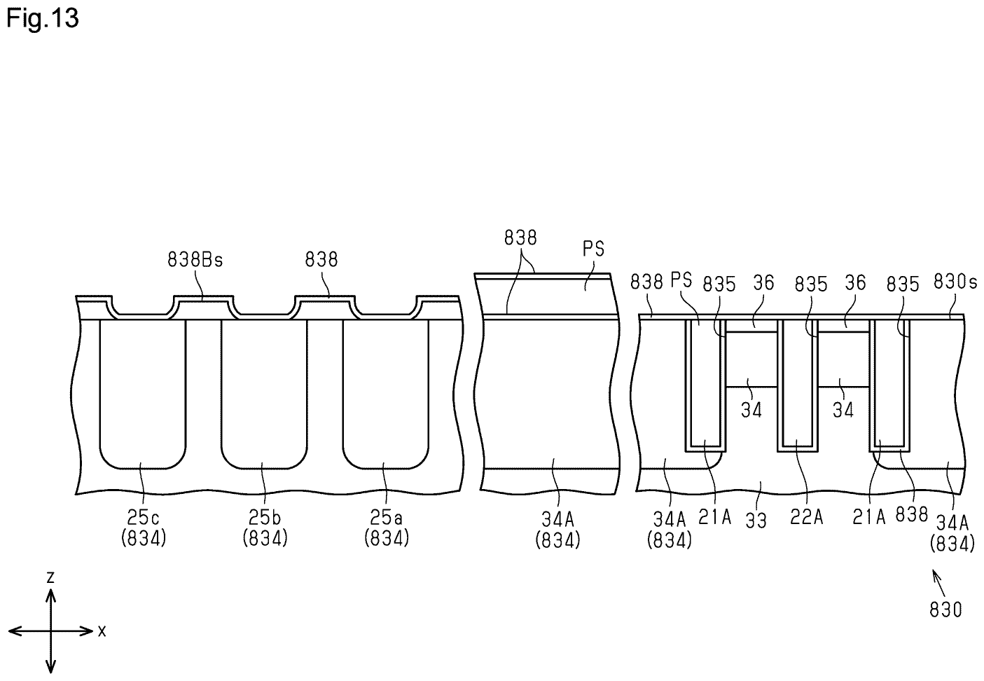

As shown in FIG. 13, the method for manufacturing the semiconductor device 10 of the present embodiment includes a step of forming the base region 34, the emitter region 36, and the channel stop region 26a (refer to FIG. 7). More specifically, the substrate front surface 830s of the semiconductor substrate 830 is selectively doped with n-type and p-type dopants through ion implantation and diffusion. This sequentially forms a p-type base region 34, an n⁺-type emitter region 36, and the channel stop region 26a. That is, the emitter region 36 and the channel stop region 26a are formed in the same step.

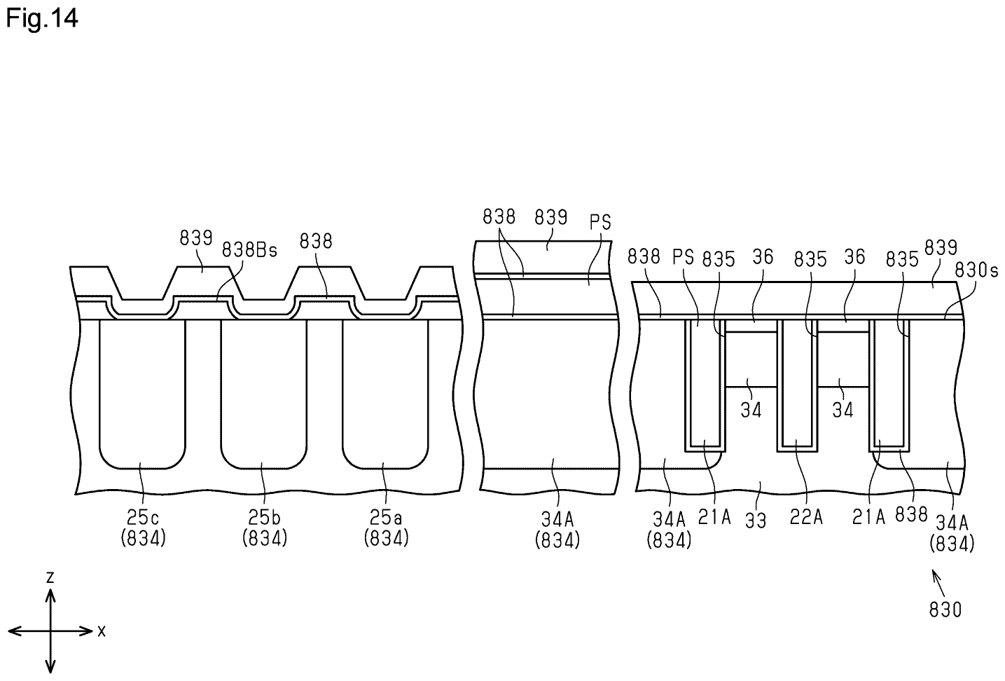

As shown in FIG. 14, the method for manufacturing the semiconductor device 10 of the present embodiment includes a step of forming an intermediate insulation film 839. The intermediate insulation film 839 is formed on the entirety of the substrate front surface 830s of the semiconductor substrate 830 by, for example, chemical vapor deposition (CVD). The intermediate insulation film 839 corresponds to the intermediate insulation film 39. The intermediate insulation film 839 is formed on the insulation film 838. In this case, in the cell region 11, the insulation film 838 and the intermediate insulation film 839 are formed on the substrate front surface 830s of the semiconductor substrate 830 to form an insulation film having a two-layer structure. In a region in which the gate electrode 22 and the gate fingers 23A and 23B are formed, the insulation film 838 and the intermediate insulation film 839 are formed on the electrode material PS to form an insulation film having a two-layer structure. In the peripheral region 12, the substrate-side insulation film 838B, the insulation film 838, and the intermediate insulation film 839 are formed on the substrate front surface 830s of the semiconductor substrate 830 to form an insulation film having a three-layer structure. In the present embodiment, the step of forming the substrate-side insulation film 838B, the insulation film 838, and the intermediate insulation film 839 corresponds to “forming an insulation film covering a surface of the first semiconductor layer and a surface of the second semiconductor region.”

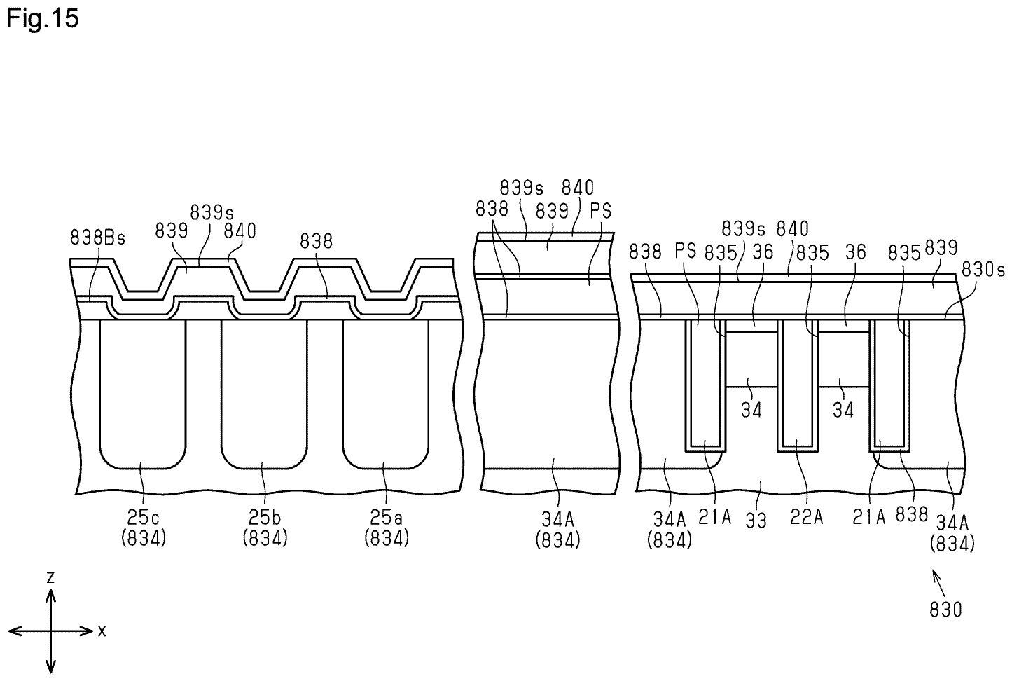

As shown in FIG. 15, the method for manufacturing the semiconductor device 10 of the present embodiment includes a step of forming a barrier layer 840. The barrier layer 840 is an insulation layer corresponding to the barrier layer 40 of the semiconductor device 10. The barrier layer 840 is formed from a material having a smaller diffusion coefficient than those of the intermediate insulation film 839 and the insulation films 838 and 838B. In the present embodiment, the barrier layer 840 is formed from a material including silicon nitride (SiN) and is, for example, formed on the entirety of a surface of 839s of the intermediate insulation film 839 through CVD.

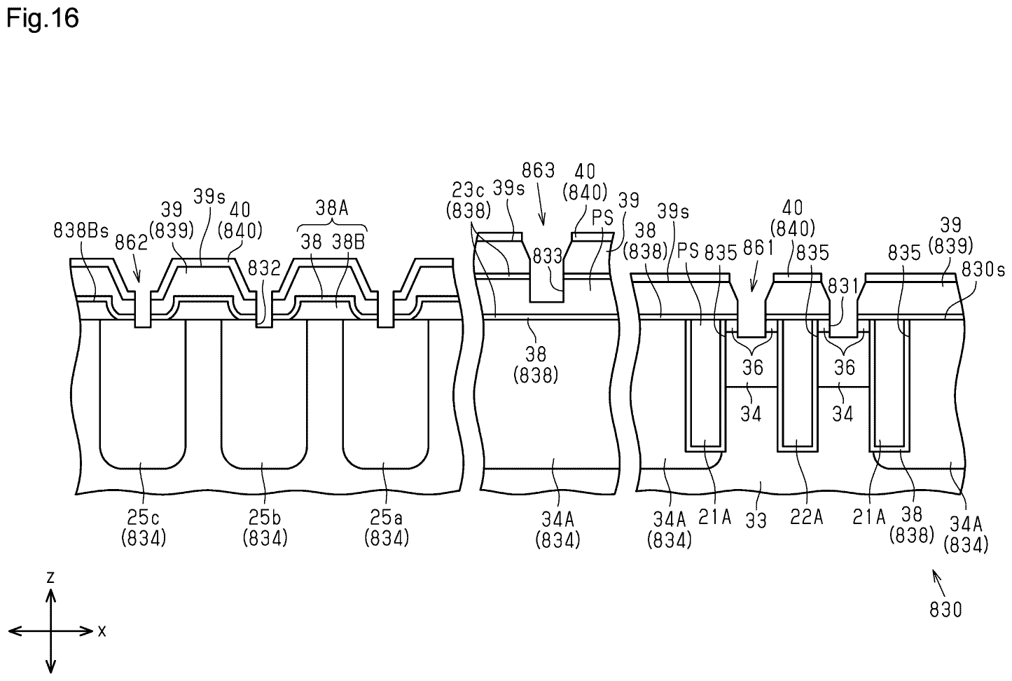

As shown in FIG. 16, the method for manufacturing the semiconductor device 10 of the present embodiment includes a step of forming openings.

In the cell region 11, openings 861 are formed by etching to extend through the barrier layer 840, the intermediate insulation film 839, and the insulation film 838. In the cell region 11, the openings 861 expose the base region 34. The openings 861 form recesses 831 in the substrate front surface 830s of the semiconductor substrate 830 corresponding to the base region 34.

In the peripheral region 12, openings 862 are formed by etching to extend through the barrier layer 840, the intermediate insulation film 839, and the insulation film 838. In the peripheral region 12, for example, the openings 862 separately expose the guard rings 25a to 25d. The openings 862 form recesses 832 in the substrate front surface 830s of the semiconductor substrate 830 corresponding to the guard rings 25a to 25d.

In the region in which the gate fingers 23A and 23B are formed, openings 863 are formed by etching to extend through the barrier layer 840, the intermediate insulation film 839, and the insulation film 838. The openings 863 in the region in which the gate fingers 23A and 23B are formed expose, for example, the electrode material. The openings 863 form recesses 833 in the surface of the electrode material. Formation of the openings 861 to 863 forms the insulation films 38 and 38A, the intermediate insulation film 39, and the barrier layer 40.

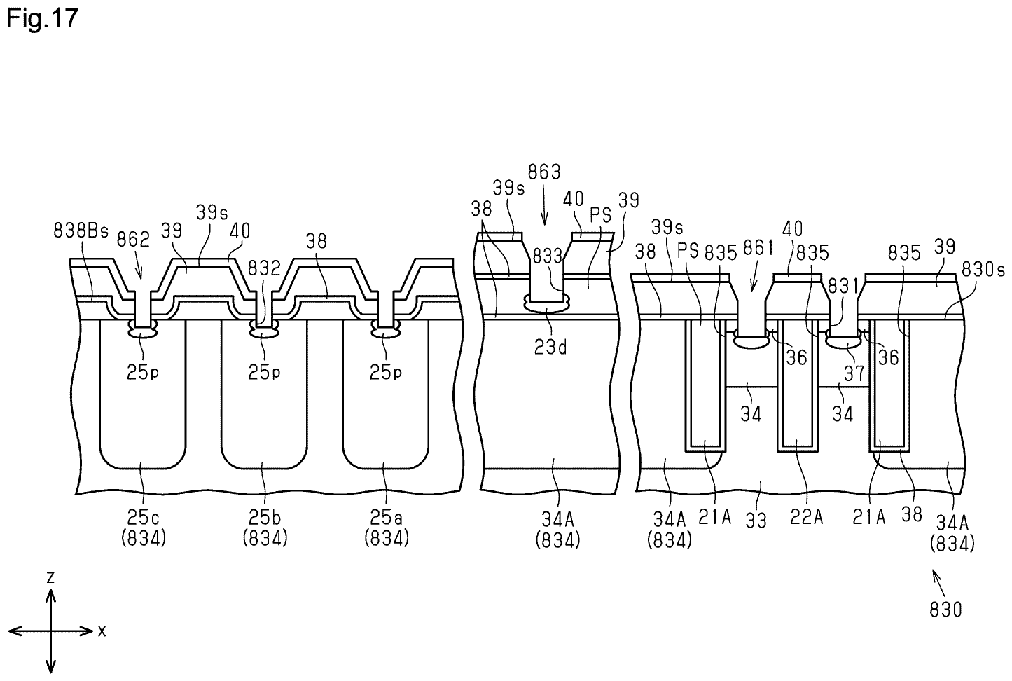

As shown in FIG. 17, the method for manufacturing the semiconductor device 10 of the present embodiment includes a step of forming the base contact region 37, the contact region 23d, the contact region 34B, and the contact region 25p. More specifically, the substrate front surface 830s of the semiconductor substrate 830 is doped with a p-type dopant through the openings through ion implantation and diffusion. This forms the base contact region 37, the contact region 23d, the contact region 34B, and the contact region 25p of p⁺-type. In FIG. 17, the base contact region 37, the contact region 23d, and the contact region 25p are shown.

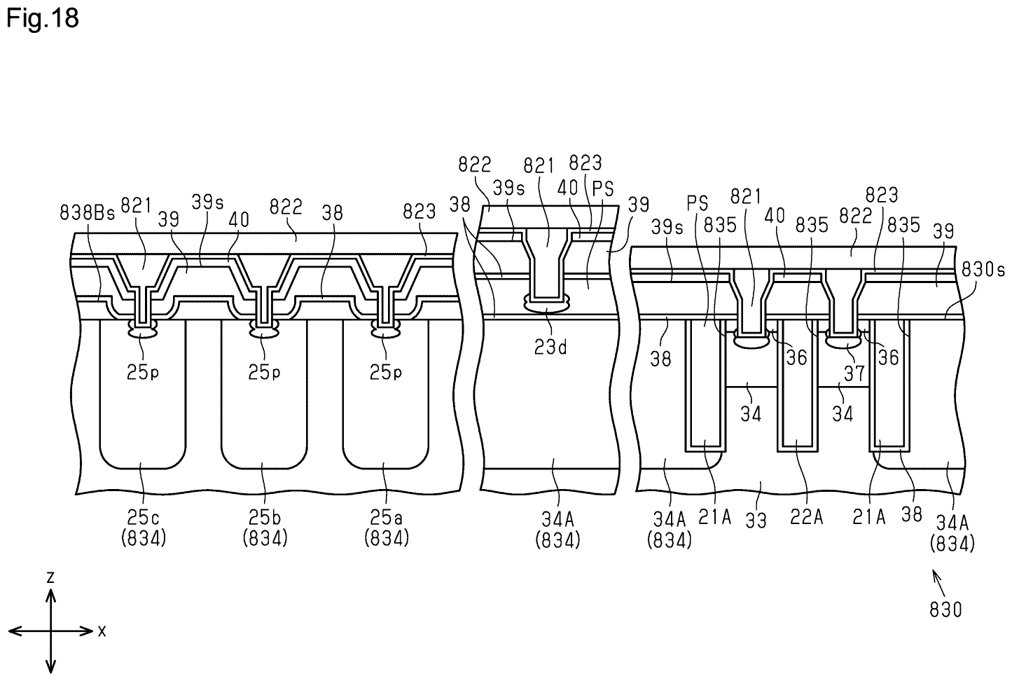

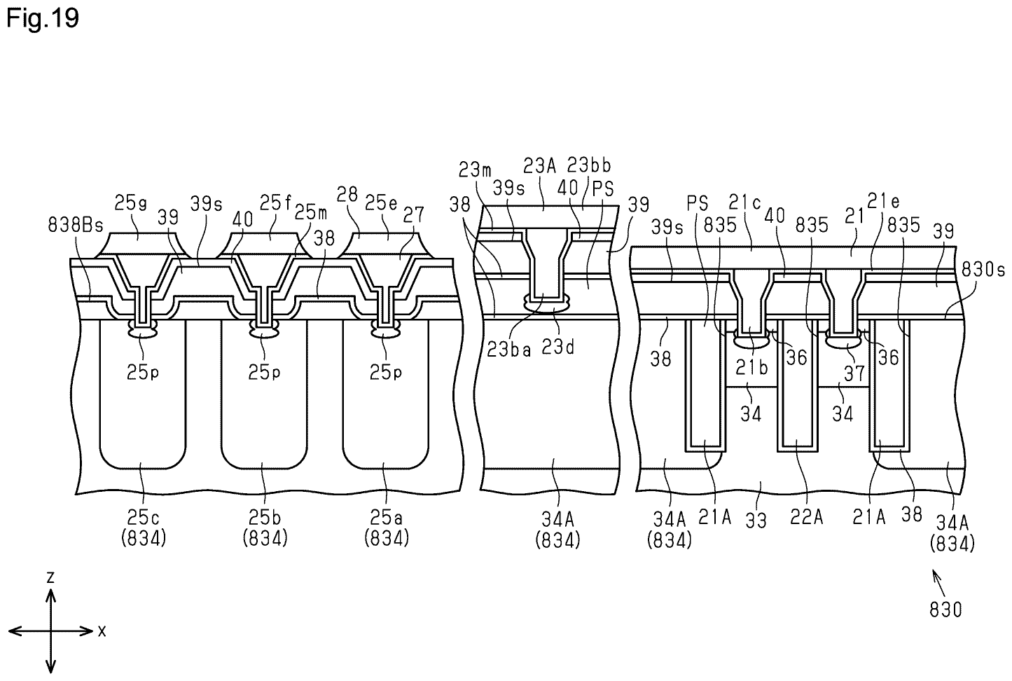

As shown in FIGS. 18 and 19, the method for manufacturing the semiconductor device 10 of the present embodiment includes a step of forming the emitter electrode 21, the gate electrode 22, the gate interconnects 23b of the gate fingers 23A and 23B, the emitter extension 24, the field plates 25e to 25h, and the equipotential ring 26. In the present embodiment, the step of forming the emitter electrode 21, the gate electrode 22, the gate interconnects 23b of the gate fingers 23A and 23B, the emitter extension 24, the field plates 25e to 25h, and the equipotential ring 26 corresponds to “forming an electrode.” In FIGS. 18 and 19, the emitter electrode 21, the gate interconnect 23b of the gate finger 23A, and the field plates 25e to 25g are shown.

As shown in FIG. 18, for example, sputtering using titanium (Ti) is performed to form a first metal layer on the surface 39s of the intermediate insulation film 39 and the wall surfaces of the openings 861 to 863. Subsequently, sputtering using titanium nitride (TiN) is performed to form a second metal layer on the first metal layer. This forms a barrier metal layer 823. The barrier metal layer 823 corresponds to the barrier metal layer 21e of the emitter electrode 21, the barrier metal layer 23m of the gate finger 23A (23B), the barrier metal layer 24m of the emitter extension 24, the barrier metal layer 25m of the field plates 25e to 25h, and the barrier metal layer 26m of the equipotential ring 26. That is, in the present embodiment, the barrier metal layers 21e, 23m, 24m, 25m, and 26m are formed in the same step.

Plug electrodes 821 including tungsten (W) are embedded in the openings 861 to 863. The plug electrodes 821 correspond to the plug electrodes 21b of the emitter electrode 21, the first part 23ba of the gate finger 23A (23B), the first part 24a of the emitter extension 24, the first part 27 of the field plates 25e to 25h, and the first parts 26f and 26g of the equipotential ring 26. That is, in the present embodiment, the plug electrodes 21b, the first parts 23ba, 24a, 27, 26f, and 26g are formed in the same step.

Subsequently, sputtering using AlCu is performed to form an electrode layer 822. The electrode layer 822 is formed on the entirety of the intermediate insulation film 39 as viewed in the z-direction. The electrode layer 822 corresponds to the electrode body 21c of the emitter electrode 21, the second part 23bb of the gate finger 23A (23B), the second part 24b of the emitter extension 24, the second part 28 of the field plates 25e to 25h, and the second part 26i of the equipotential ring 26. That is, in the present embodiment, the electrode body 21c and the second parts 23bb, 24b, 28, and 26i are formed in the same step.

As shown in FIG. 19, the electrode layer 822 is etched to form the emitter electrode 21, the gate electrode 22, the gate fingers 23A and 23B, the emitter extension 24, the field plates 25e to 25h, and the equipotential ring 26. In FIG. 19, the emitter electrode 21, the gate finger 23A, and the field plates 25e to 25g are shown.

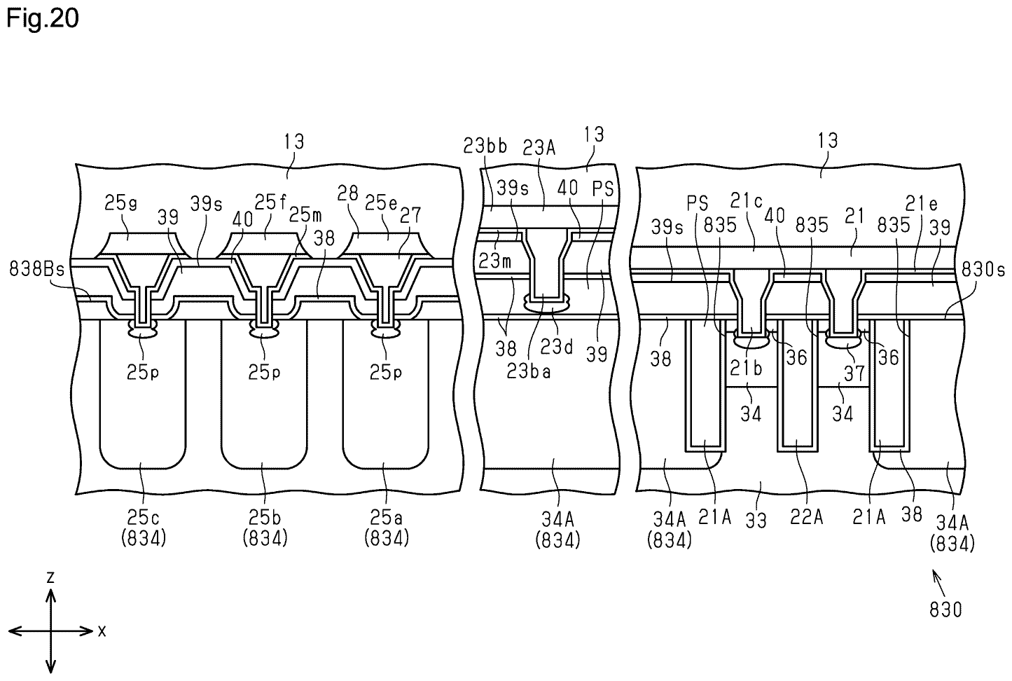

As shown in FIG. 20, the method for manufacturing the semiconductor device 10 of the present embodiment includes a step of forming the passivation film 13. More specifically, a passivation layer is formed from an organic material such as polyimide on the entirety of the substrate front surface 830s of the semiconductor substrate 830 to cover the emitter electrode 21, the gate electrode 22, the gate fingers 23A and 23B, the field plates 25e to 25h, and the equipotential ring 26 as viewed in the z-direction. Subsequently, etching is performed to expose the emitter electrode 21 and the gate electrode 22. As a result, the passivation film 13, the emitter electrode pad 16, and the gate electrode pad 17 are formed. The passivation film 13 covers the emitter electrode 21, the gate electrode 22, the gate fingers 23A and 23B, the field plates 25e to 25h, and the equipotential ring 26, and the barrier layer 40.

Although not shown, the method for manufacturing the semiconductor device 10 of the present embodiment includes a step of forming the buffer layer 32, the collector layer 31, and the collector electrode 29. More specifically, the substrate back surface of the semiconductor substrate 830 is selectively doped with n-type and p-type dopants through ion implantation and diffusion. This sequentially forms the buffer layer 32 and the collector layer 31. Subsequently, the collector electrode 29 is formed on a surface of the collector layer 31 opposite to the buffer layer 32. The steps described above manufacture the semiconductor device 10. FIGS. 8 to 20 show some of the manufacturing steps of the semiconductor device 10. The method for manufacturing the semiconductor device 10 may include steps that are not shown in FIGS. 8 to 20.

Operation of Semiconductor Device of First Embodiment

The passivation film 13, which is an organic insulation film formed from polyimide or the like, is formed on the entirety of the device main surface 10s to protect the semiconductor device 10 from external ions. Thus, the passivation film 13 covers the entirety of the peripheral region 12. However, since the passivation film 13 has a larger diffusion coefficient, external ions may diffuse and transmit through the passivation film 13.

If the intermediate insulation film 39 and the insulation films 38 and 38A, including a silicon oxide film, are charged with external ions, in particular, if the intermediate insulation film 39 and the insulation film 38A in the peripheral region 12 (e.g., FLR portion 25) are charged with external ions, the extent of electric fields of the guard rings 25a to 25d may vary. As a result, the breakdown voltage may become lower than the predetermined breakdown voltage.

In this regard, a barrier layer including a silicon nitride film having a small diffusion coefficient may be arranged to limit charging of the intermediate insulation film 39 and the insulation films 38 and 38A with external ions. In an example, when the FLR portion 25 includes a barrier layer, the barrier layer may be arranged on, for example, the surface 39s of the intermediate insulation film 39 and the surface of the field plates 25e to 25h.

However, since the surfaces of the field plates 25e to 25h and the surface 39s of the intermediate insulation film 39 are located at different positions in the z-direction, the barrier layer will have stepped portions between the surface 39s of the intermediate insulation film 39 and the surfaces of the field plates 25e to 25h. The stepped portions of the barrier layer are prone to formation of cracks. When a crack is formed in the barrier layer, external ions may enter the intermediate insulation film 39 through the crack and charge the intermediate insulation film 39.

In the present embodiment, the barrier layer 40 includes the intermediate portion 41 sandwiched between the intermediate insulation film 39 and the projection 28a of the field plates 25e to 25h. This limits formation of steps in the barrier layer 40. The portion of the intermediate insulation film 39 located below the projection 28a is protected by the barrier layer 40. This limits formation of cracks in the barrier layer 40, thereby limiting charging of the intermediate insulation film 39 with external ions caused by cracks.

Advantages of Semiconductor Device of First Embodiment

The semiconductor device 10 of the present embodiment has the following advantages.

(1-1) The peripheral region 12 of the semiconductor device 10 includes the insulation film 38A and the intermediate insulation film 39, which cover the drift layer 33 and the guard rings 25a to 25d, the field plates 25e to 25h, which extend through the insulation film 38A and the intermediate insulation film 39 and respectively contact the guard rings 25a to 25d, and the passivation film 13, which covers the insulation film 38A, the intermediate insulation film 39, and the field plates 25e to 25h. Each of the field plates 25e to 25h includes the first part 27, arranged in the openings 38c and 39c, and the second part 28, which includes the projection 28a projecting sideward from the first part 27 and overlapping with the insulation film 38A and the intermediate insulation film 39. The semiconductor device 10 includes the barrier layer 40 arranged between the passivation film 13 and the drift layer 33 and having a smaller diffusion coefficient than the insulation film 38A, the intermediate insulation film 39, and the passivation film 13. The barrier layer 40 includes a portion arranged between the projection 28a of the field plates 25e to 25h and the guard rings 25a to 25d.

In this structure, the barrier layer 40 is arranged between the projection 28a of the field plates 25e to 25h and the guard rings 25a to 25d and covers the portion of the intermediate insulation film 39 located below the projection 28a. Thus, the portion of the intermediate insulation film 39 located below the projection 28a is protected from external ions.

In addition, the portion of the barrier layer 40 arranged between the projection 28a and the guard rings 25a to 25d eliminates the need to form the barrier layer 40 on the second part 28 including the projection 28a for protecting the portion of the intermediate insulation film 39 located below the projection 28a. This avoids formation of a step in the barrier layer 40. As a result, formation of cracks in the barrier layer 40 is limited. This limits charging of the intermediate insulation film 39, corresponding to the FLR portion 25, with external ions and limits a decrease in the dielectric strength of the FLR portion 25.

Further, the structure of the barrier layer 40 for the emitter extension 24 and the gate fingers 23A and 23B is the same as the structure of the barrier layer 40 for the FLR portion 25. Thus, the barrier layer 40 also limits formation of cracks in the emitter extension 24 and the gate fingers 23A and 23B.

(1-2) The barrier layer 40 is formed on the surface 39s of the intermediate insulation film 39. The barrier layer 40 includes the intermediate portion 41 sandwiched between the intermediate insulation film 39 and the projection 28a of the field plates 25e to 25h.

In this structure, the barrier layer 40 is shaped in conformance with the surface 39s of the intermediate insulation film 39. That is, the barrier layer 40 is not formed on the surface of the field plates 25e to 25h. More specifically, the barrier layer 40 does not cover the field plates 25e to 25h including the second parts 28. The field plates 25e to 25h are exposed from the barrier layer 40. This limits formation of steps in the barrier layer 40. As a result, formation of cracks in the barrier layer 40 is limited. Further, the structure of the barrier layer 40 for the emitter extension 24 and the gate fingers 23A and 23B is the same as the structure of the barrier layer 40 for the FLR portion 25. Thus, the barrier layer 40 also limits formation of cracks in the emitter extension 24 and the gate fingers 23A and 23B.

(1-3) The intermediate portion 41 of the barrier layer 40 includes the barrier layer opening 40c. The wall surface 40d defining the barrier layer opening 40c is flush with the wall surface 39d of the intermediate insulation film 39 defining the opening 39c.

In this structure, the intermediate portion 41 of the barrier layer 40 is formed in the entire region in which the projection 28a of the field plates 25e to 25h overlaps with the intermediate insulation film 39 as viewed in the z-direction. This further limits charging of the intermediate insulation film 39 with external ions.

(1-4) As viewed in the z-direction, the barrier layer 40 extends over the outer edges of the guard rings 25a to 25d.

This structure limits charging of the intermediate insulation film 39 with external ions in the region where the intermediate insulation film 39 overlaps the guard rings 25a to 25d as viewed in the z-direction. This limits a decrease in the dielectric strength of the FLR portion 25.

(1-5) The thickness of the barrier layer 40 is less than the thickness of the intermediate insulation film 39.

This structure facilitates manufacturing of the barrier layer 40 and reduces manufacturing costs of the semiconductor device 10.

(1-6) The projection 28a of the second part 28 of the field plates 25e to 25h is arranged to overlap the guard rings 25a to 25d, respectively, as viewed in the z-direction. The intermediate portion 41 of the barrier layer 40 is disposed between the projection 28a of the field plates 25e to 25h and the guard rings 25a to 25d. This protects the portion of the intermediate insulation film 39 that is formed on the guard rings 25a to 25d and covered by the projection 28a of the field plates 25e to 25h.

(1-7) The method for manufacturing the semiconductor device 10 includes the step of forming the insulation film 38A and the intermediate insulation film 39 on the drift layer 33 and the guard rings 25a to 25d in the peripheral region 12, the step of forming the barrier layer 40, having a smaller diffusion coefficient than the intermediate insulation film 39, on the surface 39s of the intermediate insulation film 39, the step of forming the field plates 25e to 25h having the first part 27 arranged in the opening 39c of the intermediate insulation film 39 and the second part 28 including the projection 28a projecting sideward from the first part 27 and overlapping with the intermediate insulation film 39 and the barrier layer 40, and the step of forming the passivation film 13 covering the barrier layer 40 and the field plates 25e to 25h. This structure obtains the same advantage as (1-1).

### Second Embodiment

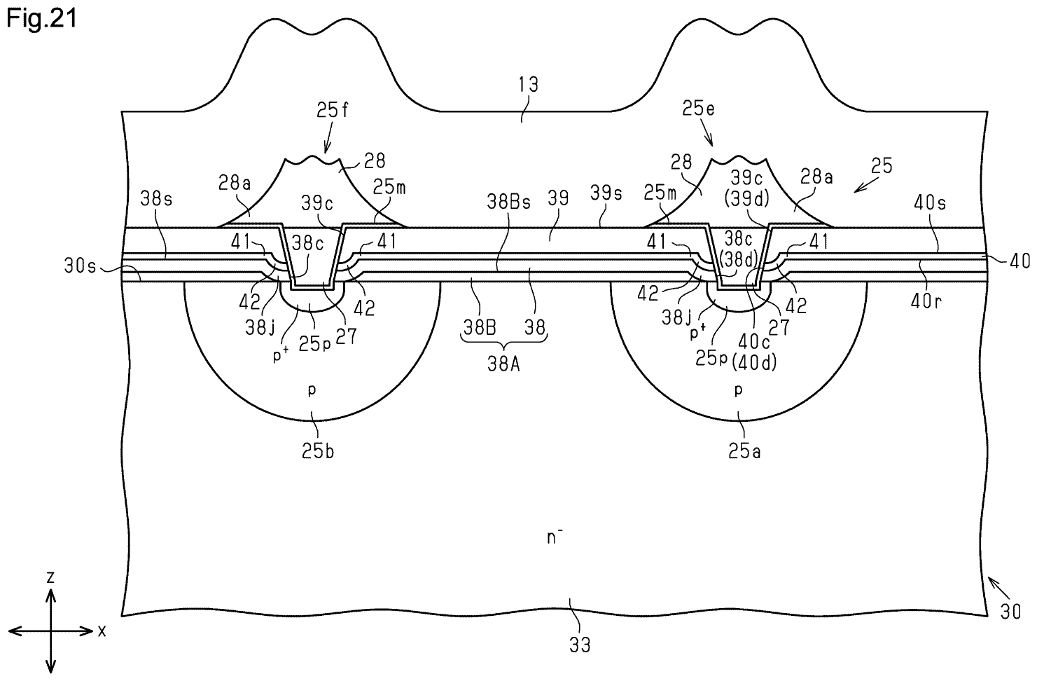

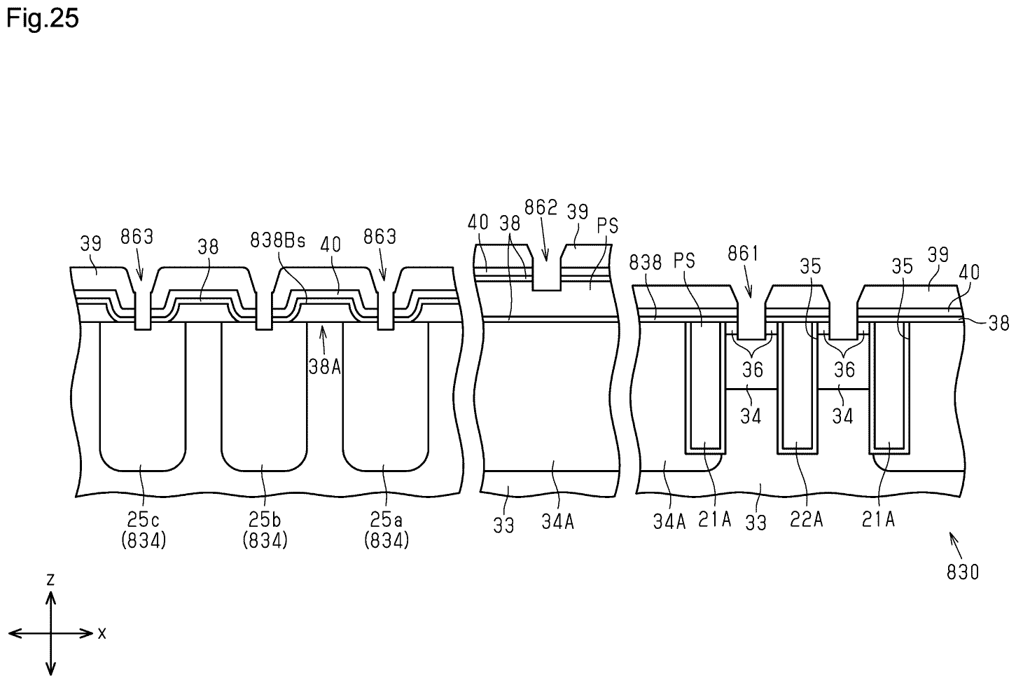

A second embodiment of a semiconductor device 10 will now be described with reference to FIGS. 21 and 25. The present embodiment differs in the position of the barrier layer 40. In the following description, differences from the semiconductor device 10 of the first embodiment will be described in detail. Same reference characters are given to those components that are the same as the corresponding components of the semiconductor device 10 of the first embodiment. Such components will not be described in detail.

Structure of Semiconductor Device

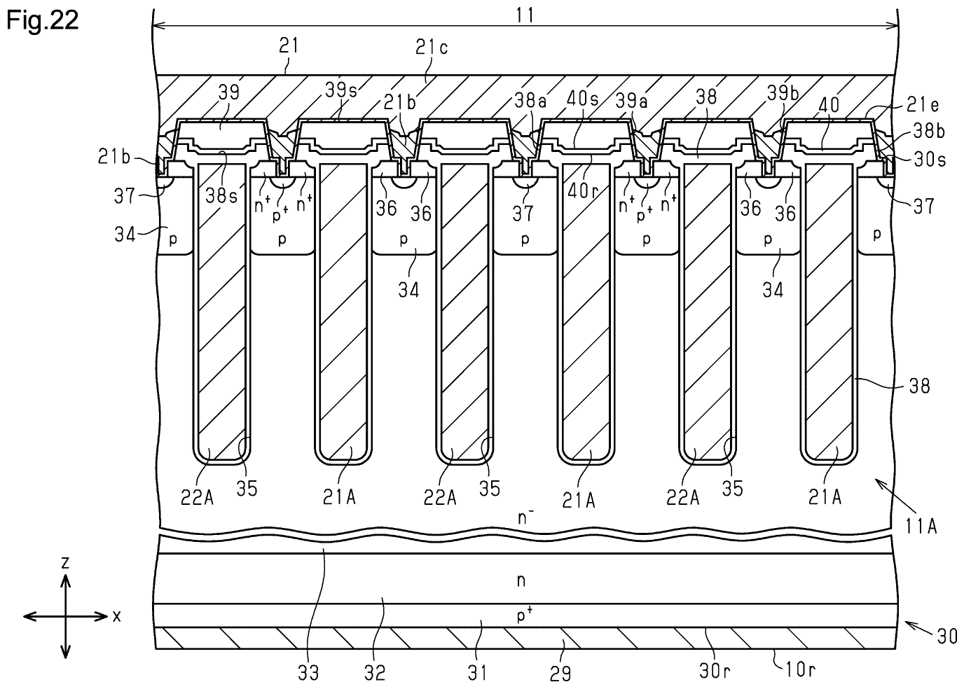

The structure of the semiconductor device 10 according to the present embodiment will now be described with reference to FIGS. 21 and 22. FIG. 21 is a diagram showing the cross-sectional structure of a portion of the FLR portion 25 in the peripheral region 12. Although not shown, the position of the barrier layer 40 arranged on the gate fingers 23A and 23B and the equipotential ring 26 is the same as the position of the barrier layer 40 arranged in the FLR portion 25. For the sake of convenience, FIGS. 21 and 22 do not show hatching of some or all of the components of the semiconductor device 10.

As shown in FIG. 21, in the peripheral region 12, the barrier layer 40 is formed on the surface 38s of the insulation film 38, which is the surface of the insulation film 38A, and is covered by the intermediate insulation film 39. In other words, the barrier layer 40 is sandwiched between the insulation film 38A and the intermediate insulation film 39. Also, in other words, the intermediate insulation film 39 is formed on the insulation film 38A. The intermediate insulation film 39 is covered by the passivation film 13. Therefore, in the present embodiment, the barrier layer 40 is not in contact with the passivation film 13.

In the present embodiment, the barrier layer 40 includes an opening end that is shaped in conformance with the shape of an opening end of the insulation film 38A defining the opening 38c. More specifically, the opening end of the insulation film 38A includes a curved portion 38j as in the first embodiment. The barrier layer 40 includes a curved portion 42 covering the curved portion 38j. In the same manner as the curved portion 38j of the insulation film 38A, the curved portion 42 is curved toward the substrate front surface 30s of the semiconductor substrate 30 as the center of the barrier layer opening 40c becomes closer. The curved portion 42 of the barrier layer 40 is covered by the intermediate insulation film 39. In other words, the intermediate insulation film 39 covers the curved portion 38j of the insulation film 38A.

The barrier layer 40 includes an intermediate portion 41 arranged between the projection 28a of the field plate 25e and the guard ring 25a. In the present embodiment, the intermediate portion 41 is a portion of the barrier layer 40 that overlaps with the projection 28a of the field plate 25e and the guard ring 25a as viewed in the z-direction. In the present embodiment, the intermediate portion 41 is separated from the projection 28a and the guard ring 25a in the z-direction. The intermediate portion 41 includes a barrier layer opening 40c. Thus, as viewed in the z-direction, the intermediate portion 41 extends to the edge of the insulation film 38A defining the opening 38c, through which the first part 27 of the field plate 25e is inserted. The intermediate portion 41 is in contact with the first part 27. The barrier layer 40 includes intermediate portions 41 for the other field plates 25f to 25h and the other guard rings 25b to 25d in the same manner as the first embodiment.

The barrier layer 40 extends over the guard rings 25a to 25d as viewed in the z-direction. Thus, the barrier layer 40 covers the entirety of the guard rings 25a to 25d excluding a position overlapping the first part 27 of the field plates 25e to 25h as viewed in the z-direction.

As shown in FIG. 22, in the cell region 11, the barrier layer 40 is formed on the surface 38s of the insulation film 38, which corresponds to a gate oxide film, and is covered by the intermediate insulation film 39. In the cell region 11, the barrier layer 40 is formed between the insulation film 38 and the intermediate insulation film 39. In other words, in the cell region 11, the barrier layer 40 is sandwiched between the insulation film 38 and the intermediate insulation film 39 in contact with the insulation film 38 and the intermediate insulation film 39. The barrier layer 40 is formed in conformance with the shape of the surface 38s of the insulation film 38. In other words, the intermediate insulation film 39 is formed on the insulation film 38.

Semiconductor Device Manufacturing Method

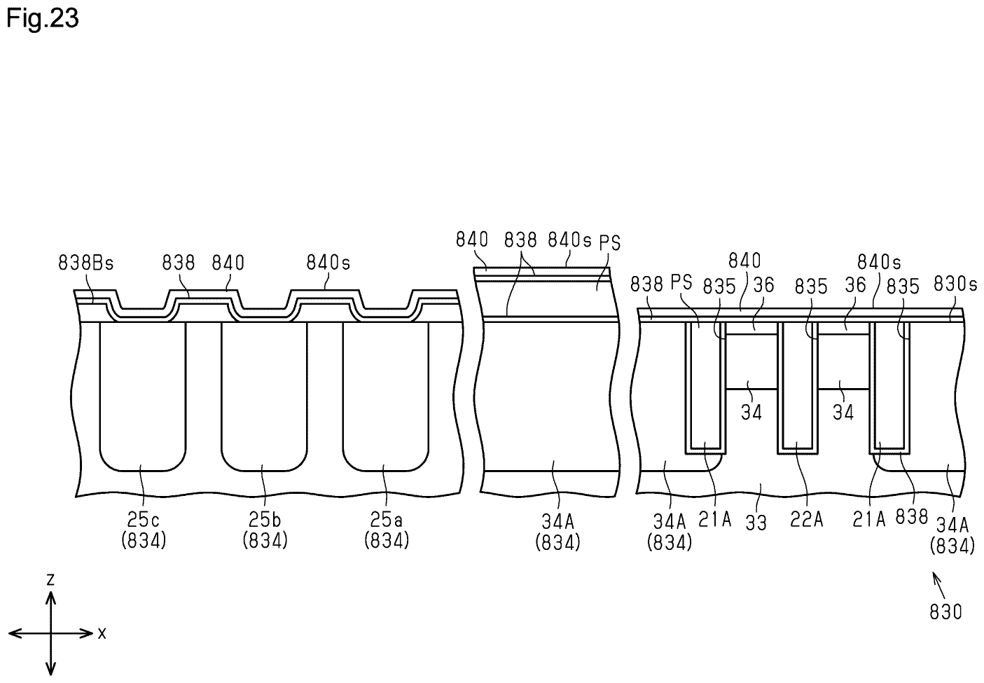

A method for manufacturing the semiconductor device 10 of the present embodiment will be described with reference to FIGS. 23 to 25. The method for manufacturing the semiconductor device 10 of the present embodiment differs from the method for manufacturing the semiconductor device 10 of the first embodiment in the order of the step of forming the barrier layer 840. In the following description, the differences from the first embodiment will be described. The same manufacturing steps as those in the first embodiment will not be described.

As shown in FIG. 23, in the method for manufacturing the semiconductor device 10 of the present embodiment, a step of forming the barrier layer 840 is performed subsequent to a step of forming the base region 34 and the emitter region 36 and prior to a step of forming the intermediate insulation film 839. That is, the step of forming the barrier layer 840 is performed subsequent to a step of forming the insulation films 838 and 838B. In an example, the barrier layer 840 is formed on the entire surface of the insulation film 838 by CVD. The barrier layer 840 is formed from the same material as that forming the barrier layer 840 of the first embodiment. In the present embodiment, the steps are the same as those in the first embodiment, until the step of forming the base region 34 and the emitter region 36.

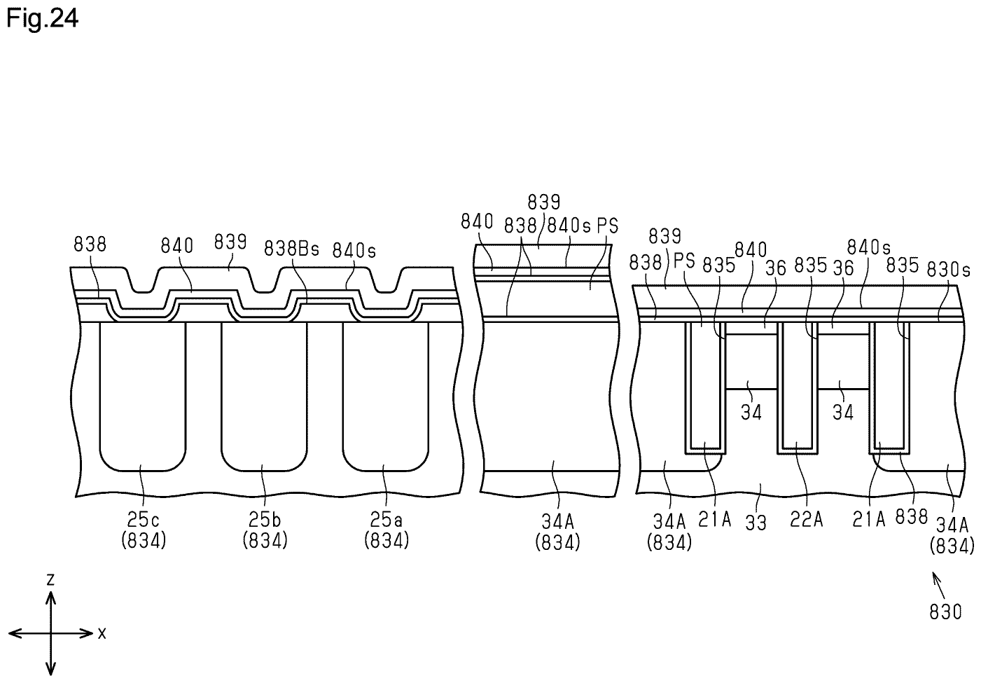

As shown in FIG. 24, in an example of a step of forming the intermediate insulation film 839, the intermediate insulation film 839 is formed on the entirety of a surface 840s of the barrier layer 840 by CVD. In the present embodiment, the step of forming the intermediate insulation film 839 corresponds to “step of forming second insulation film that covers a surface of a barrier layer.”

As shown in FIG. 25, the openings 861 to 863 are formed. The steps described above form the insulation films 38 and 38A, the intermediate insulation film 39, and the barrier layer 40. The subsequent manufacturing steps are the same as in the method for manufacturing the semiconductor device 10 of the first embodiment.

### Advantages of Second Embodiment

The semiconductor device of the present embodiment has the following advantages.

(2-1) The semiconductor device 10 includes the insulation films 38 and 38A, the intermediate insulation film 39 formed on the insulation films 38 and 38A, the barrier layer 40 formed on the surface 38s of the insulation films 38 and 38A and covered by the intermediate insulation film 39, and the passivation film 13 covered by the intermediate insulation film 39.

In this structure, the barrier layer 40 is arranged between the projection 28a of the field plates 25e to 25h and the guard rings 25a to 25d. Thus, the barrier layer 40 is not formed at the surface side of the field plates 25e to 25h. This limits formation of steps in the barrier layer 40. As a result, formation of cracks in the barrier layer 40 is limited. This limits charging of the insulation film 38, corresponding to the FLR portion 25, with external ions and limits a decrease in the dielectric strength of the FLR portion 25.

Further, the structure of the barrier layer 40 for the emitter extension 24 and the gate fingers 23A and 23B is the same as the structure of the barrier layer 40 for the FLR portion 25. Thus, the barrier layer 40 also limits formation of cracks in the emitter extension 24 and the gate fingers 23A and 23B.

(2-2) The method for manufacturing the semiconductor device includes the step of forming the insulation film 38A covering the surface of the drift layer 33 and the surface of the guard rings 25a to 25d, the step of forming the barrier layer 40, having a smaller diffusion coefficient than the insulation film 38, on the surface 38s of the insulation film 38 in the insulation film 38A, the step of forming the intermediate insulation film 39 that covers the front surface 40s of the barrier layer 40, the step of forming the field plates 25e to 25h including the first part 27 arranged in the barrier layer opening 40c and the openings 39c and 38c and the second part 28 including the projection 28a projecting sideward from the first part 27 and overlapping with the intermediate insulation film 39 and the barrier layer 40, and the step of forming the passivation film 13 covering the intermediate insulation film 39 and the field plates 25e to 25h. This structure obtains the same advantage as (2-1).

### Third Embodiment

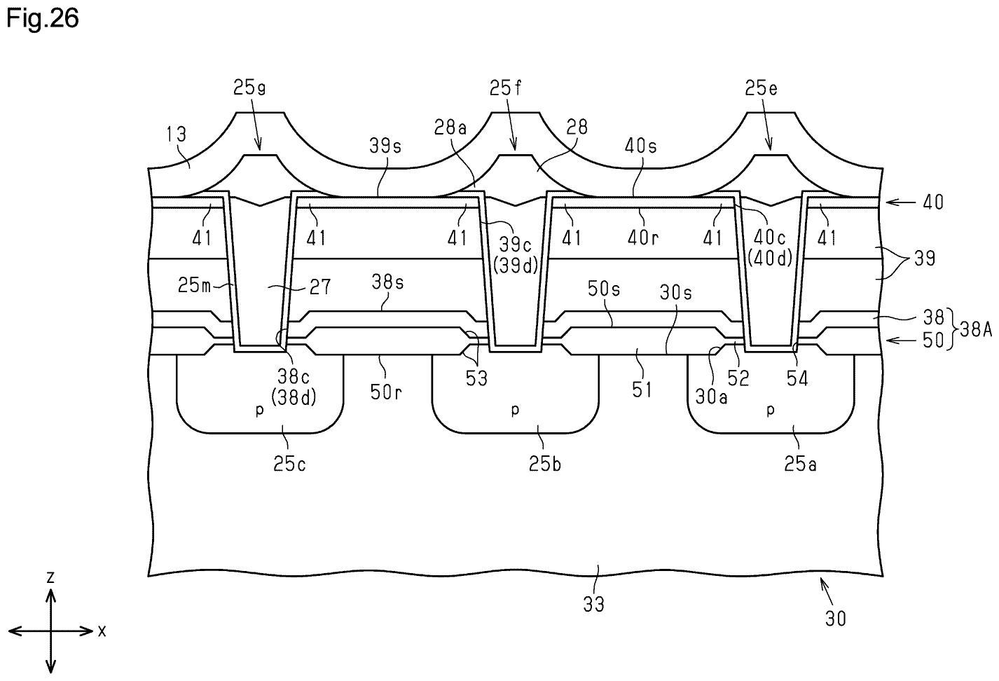

A third embodiment of a semiconductor device 10 will now be described with reference to FIGS. 26 to 33. The present embodiment differs in shape of an insulation film formed on the substrate front surface 30s of the semiconductor substrate 30. In the following description, differences from the semiconductor device 10 of the first embodiment will be described in detail. Same reference characters are given to those components that are the same as the corresponding components of the semiconductor device 10 of the first embodiment. Such components will not be described in detail.

Structure of Semiconductor Device

The structure of the semiconductor device 10 according to the present embodiment will now be described with reference to FIG. 26. For the sake of convenience, FIG. 26 does not show hatching of the components of the semiconductor device 10.

As shown in FIG. 26, instead of the substrate-side insulation film 38B, a local oxidation of silicon (LOCOS) oxide film 50 is formed on the substrate front surface 30s of the semiconductor substrate 30. Thus, in the present embodiment, the insulation film 38A is formed of the LOCOS oxide film 50 and the insulation film 38 having a stacked structure. The LOCOS oxide film 50 includes a front surface 50s and a back surface 50r facing opposite directions in the z-direction. The back surface 50r of the LOCOS oxide film 50 is in contact with the substrate front surface 30s of the semiconductor substrate 30.

The LOCOS oxide film 50 includes a thick portion 51, a thin portion 52, and a slope portion 53.

The thick portion 51 is a portion of the LOCOS oxide film 50 having a relatively large thickness and is, for example, arranged between adjacent ones of the guard rings 25a to 25d. The thin portion 52 is a portion of the LOCOS oxide film 50 having a relatively small thickness and is, for example, arranged to overlap the guard rings 25a to 25d as viewed in the z-direction. The slope portion 53 is located between the thick portion 51 and the thin portion 52 and connects the thick portion 51 and the thin portion 52. The slope portion 53 slopes at the front surface 50s and the back surface 50r so that the thickness of the LOCOS oxide film 50 increases from the thin portion 52 toward the thick portion 51.

The thick portion 51 extends into the substrate front surface 30s of the semiconductor substrate 30. Thus, the semiconductor substrate 30 includes a recess 30a recessed from the substrate front surface 30s.

The thin portion 52 includes an opening 54 extending through the thin portion 52 in the z-direction. Thus, the guard rings 25a to 25d are partially exposed from the LOCOS oxide film 50. As viewed in the z-direction, each of the guard rings 25a to 25d is greater in area than the opening 54. The structure of the LOCOS oxide film 50 may be changed in any manner. In an example, the thin portion 52 may be omitted from the LOCOS oxide film 50. In this case, the LOCOS oxide film 50 has a structure including oxide films of the thick portion 51 and the slope portion 53 separated from each other.

In the present embodiment, the insulation film 38 is formed on the front surface 50s of the LOCOS oxide film 50. The insulation film 38 is formed on the LOCOS oxide film 50 in conformance with the shape of the LOCOS oxide film 50. More specifically, the insulation film 38 slopes on the slope portion 53 of the LOCOS oxide film 50 in conformance with the shape of the slope portion 53. In the present embodiment, the insulation film 38 is formed on the entirety of the front surface 50s of the LOCOS oxide film 50. The intermediate insulation film 39 is formed on the surface 38s of the insulation film 38. Thus, the intermediate insulation film 39 entirely covers the thick portion 51, the thin portion 52, and the slope portion 53 of the LOCOS oxide film 50. In the present embodiment, the intermediate insulation film 39 has a two-layer stacked structure.

A barrier layer 40 is formed on a surface 39s of the intermediate insulation film 39. In the present embodiment, the barrier layer 40 is formed in conformance with the shape of the surface 39s of the intermediate insulation film 39. The thickness of the barrier layer 40 is greater than or equal to the thickness of the thin portion 52 of the LOCOS oxide film 50. The thickness of the barrier layer 40 is less than the thickness of the thick portion 51 of the LOCOS oxide film 50. The thickness of the barrier layer 40 may be any thickness and, for example, less than the thickness of the thin portion 52 of the LOCOS oxide film 50.

The field plate 25e includes a first part 27 arranged in the openings 54 and 39c and the barrier layer opening 40c and a second part 28 including the projection 28a projecting outward from the first part 27 and overlapping the intermediate insulation film 39. The structure of the first part 27 and the second part 28 is the same as that of the first embodiment.

The barrier layer 40 includes an intermediate portion 41 arranged between the projection 28a of the field plate 25e and the guard ring 25a. In the present embodiment, in the same manner as the first embodiment, the intermediate portion 41 is sandwiched between the projection 28a of the field plate 25e and the intermediate insulation film 39. In other words, the barrier layer 40 includes a portion (intermediate portion 41) sandwiched between the projection 28a of the field plate 25e and the intermediate insulation film 39. The intermediate portion 41 includes the barrier layer opening 40c, through which the first part 27 of the field plate 25e is inserted. Thus, as viewed in the z-direction, the intermediate portion 41 extends to the edge of the intermediate insulation film 39 defining the opening 39c, through which the first part 27 of the field plate 25e is inserted. The barrier layer 40 includes intermediate portions 41 for the other field plates 25f to 25h and the other guard rings 25b to 25d in the same manner as the first embodiment.

Semiconductor Device Manufacturing Method

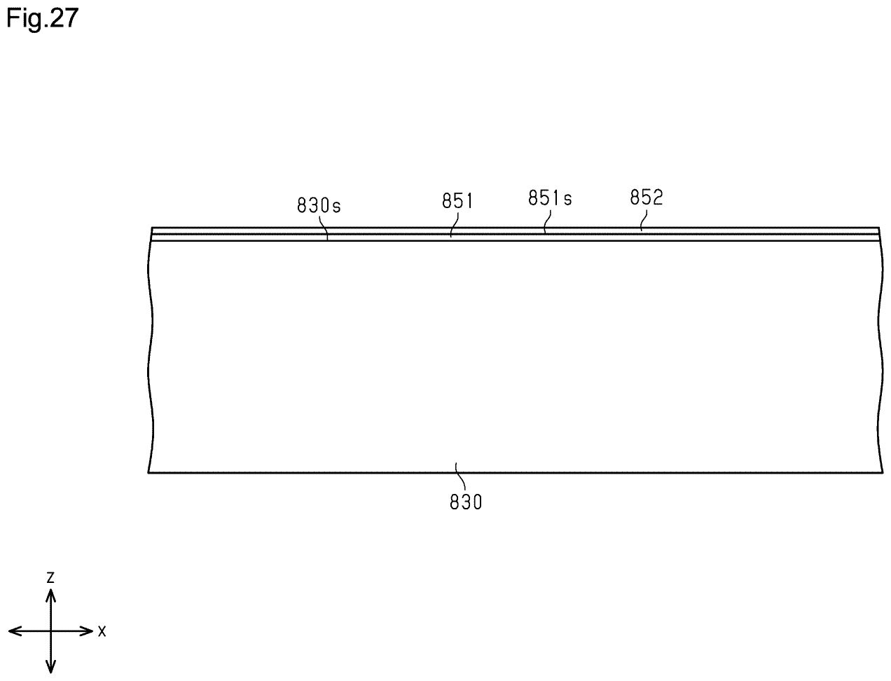

A method for manufacturing the semiconductor device 10 of the present embodiment will be described with reference to FIGS. 27 to 33. The method for manufacturing the semiconductor device 10 of the present embodiment differs from the method for manufacturing the semiconductor device 10 of the first embodiment in the process of forming an insulation film on the substrate front surface 830s of the semiconductor substrate 830. In the following description, the differences from the first embodiment will be described. The same manufacturing steps as those in the first embodiment will not be described. In the method for manufacturing the semiconductor device 10 of the present embodiment, the process for manufacturing the FLR portion 25 will be mainly described for the sake of convenience.

As shown in FIGS. 27 to 29, the method for manufacturing the semiconductor device 10 of the present embodiment includes a step of forming a LOCOS oxide film 850.

As shown in FIG. 27, the semiconductor substrate 830 formed from a material including Si is prepared. The semiconductor substrate 830 includes the drift layer 33. An oxide film 851 is formed on the entirety of the substrate front surface 830s of the semiconductor substrate 830 by, for example, CVD. The oxide film 851 includes, for example, a silicon oxide film (SiO₂ film). Subsequently, a mask 852 is formed on the entirety of a surface 851s of the oxide film 851 by CVD. The mask 852 includes, for example, a silicon nitride film (Si₃N₄ film).

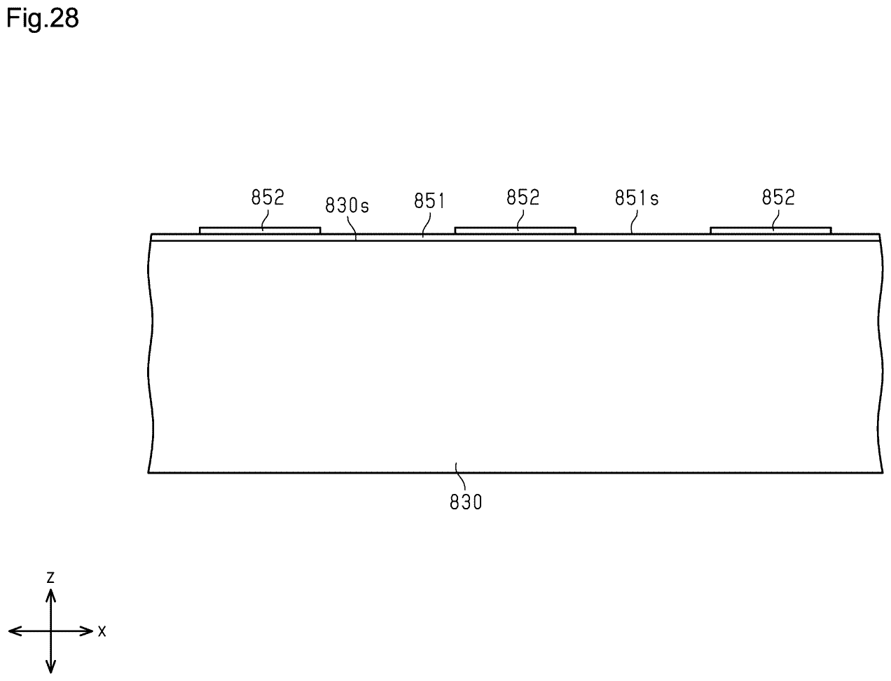

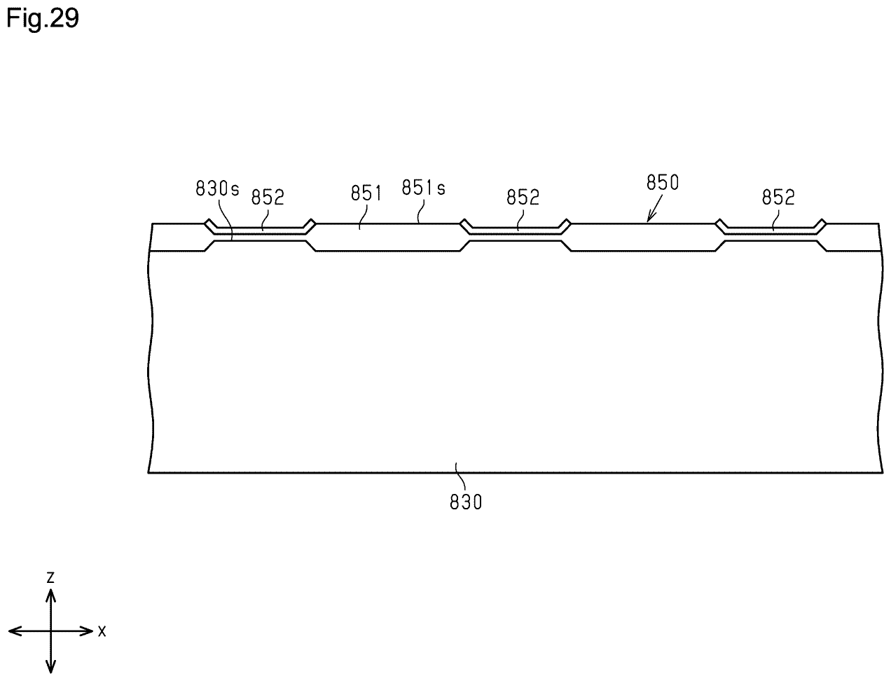

As shown in FIG. 28, the mask 852 is selectively etched. As a result, the oxide film 851 is partially exposed from the mask 852. In other words, the mask 852 is formed on a portion of the surface of the drift layer 33. As shown in FIG. 29, the oxide film 851 is grown through thermal oxidation. As a result, the portion of the oxide film 851 that is not covered by the mask 852 is increased in thickness. In contrast, in the portion of the oxide film 851 that is covered by the mask 852, growth of the oxide film 851 through thermal oxidation is limited. Thus, the oxide film 851 is partially increased in thickness. The steps described above form the LOCOS oxide film 850. Subsequently, the mask 852 is removed.

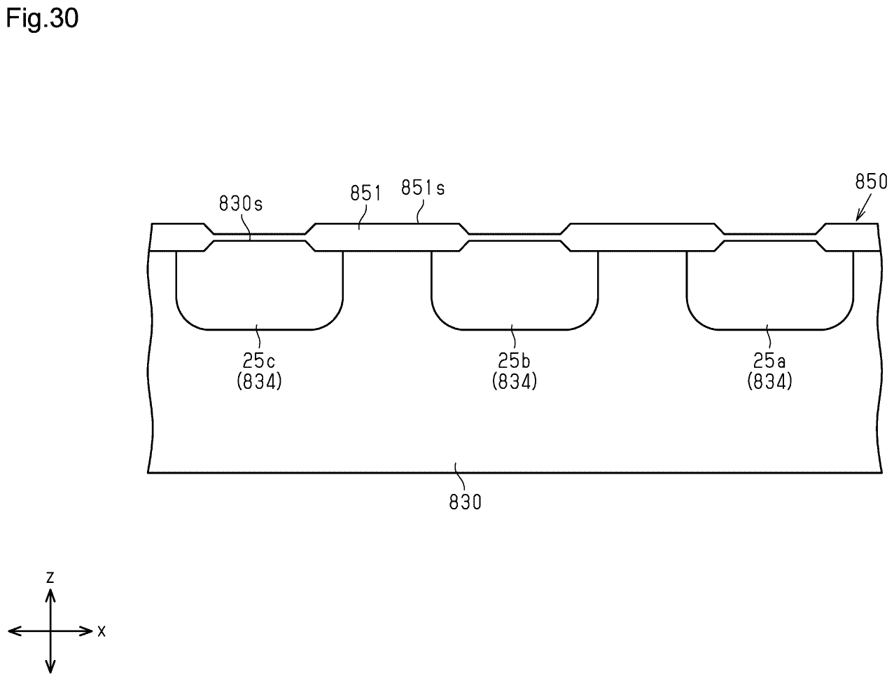

As shown in FIG. 30, the method for manufacturing the semiconductor device 10 of the present embodiment includes a step of forming a p-type well region 834, corresponding to a semiconductor region of a second conductive type. More specifically, the substrate front surface 830s of the semiconductor substrate 830 is selectively doped with a p-type impurity. Subsequently, the semiconductor substrate 830 is heated so that the p-type impurity diffuses. As a result, the well region 834 is formed. In FIG. 30, the well region 834 includes the guard rings 25a to 25c.

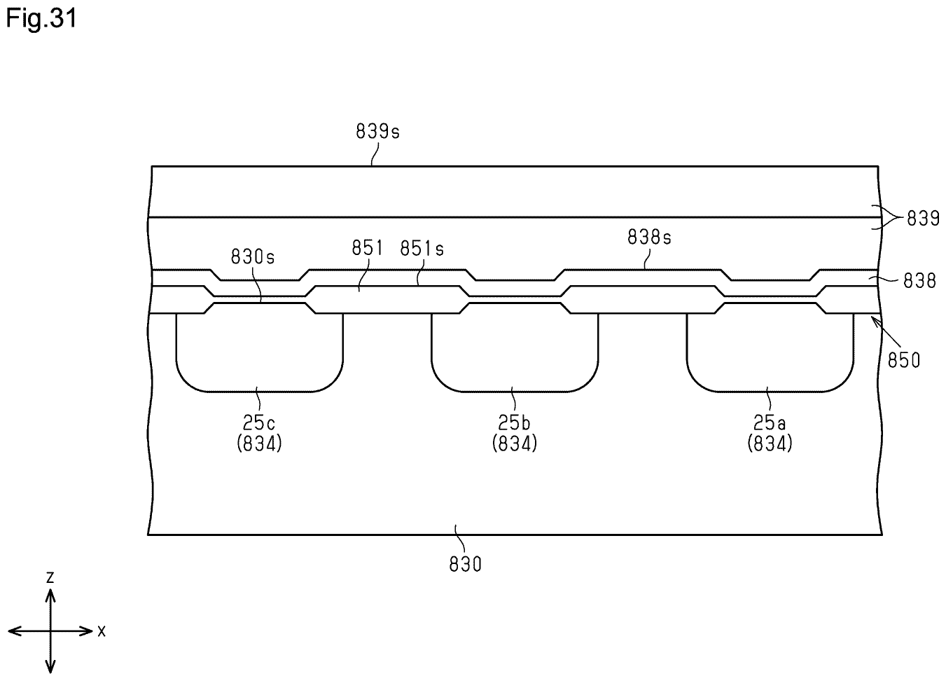

As shown in FIG. 31, the method for manufacturing the semiconductor device 10 of the present embodiment includes a step of forming an insulation film 838 and an intermediate insulation film 839. The insulation film 838 and the intermediate insulation film 839 are formed in the same process as those in the first embodiment. The insulation film 838 is formed on the surface 851s of the oxide film 851. The intermediate insulation film 839 is formed on a surface 838s of the insulation film 838.

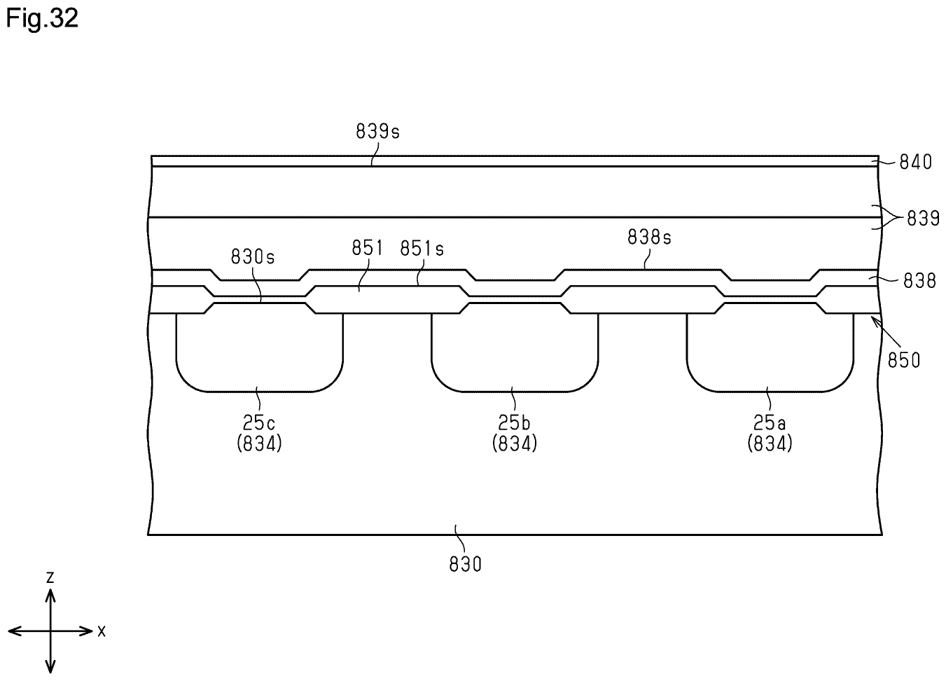

As shown in FIG. 32, the method for manufacturing the semiconductor device 10 of the present embodiment includes a step of forming a barrier layer 840. The step of forming the barrier layer 840 is the same as in the first embodiment.

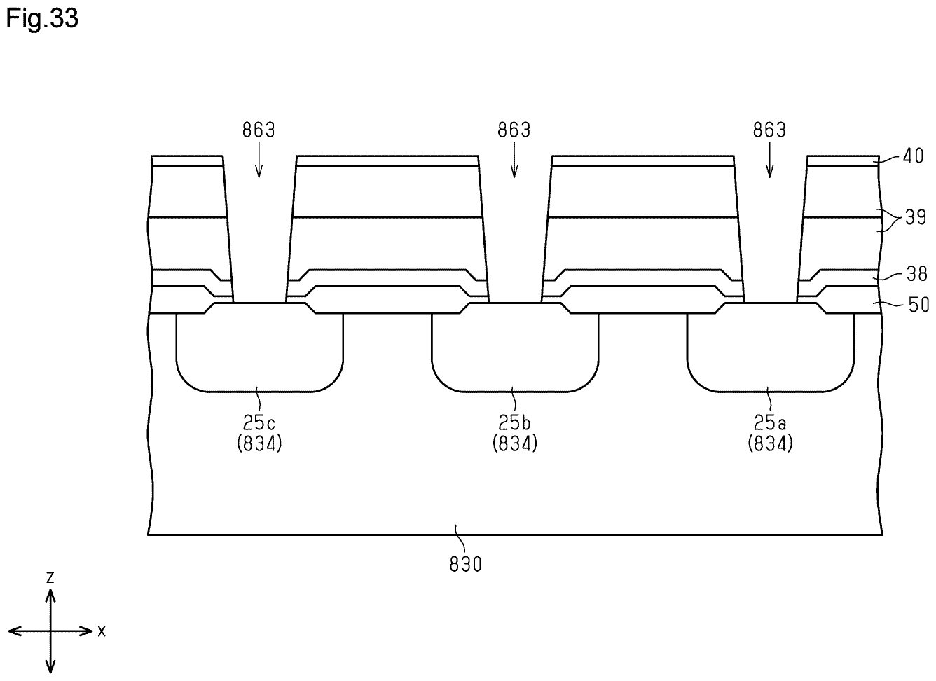

As shown in FIG. 33, the method for manufacturing the semiconductor device 10 of the present embodiment includes a step of forming openings 863. The openings 863 are formed in the same process as those in the first embodiment. As a result, the LOCOS oxide film 50, the insulation film 38, the intermediate insulation film 39, and the barrier layer 40 are formed. The subsequent steps are the same as those in the first embodiment. The semiconductor device 10 of the present embodiment has the same advantages as the first embodiment.

### Modified Examples

The above-described embodiments exemplify, without any intention to limit, applicable forms of a semiconductor device and a method for manufacturing a semiconductor device according to the present disclosure. The semiconductor device and the method for manufacturing a semiconductor device according to the present disclosure may be applicable to forms differing from the above embodiments. In an example of such a form, the structure of the embodiments is partially replaced, changed, or omitted, or a further structure is added to the embodiments. The modified examples described below may be combined with one another as long as there is no technical inconsistency. In the modified examples, the same reference characters are given to those components that are the same as the corresponding components of the above embodiments. Such components will not be described in detail.

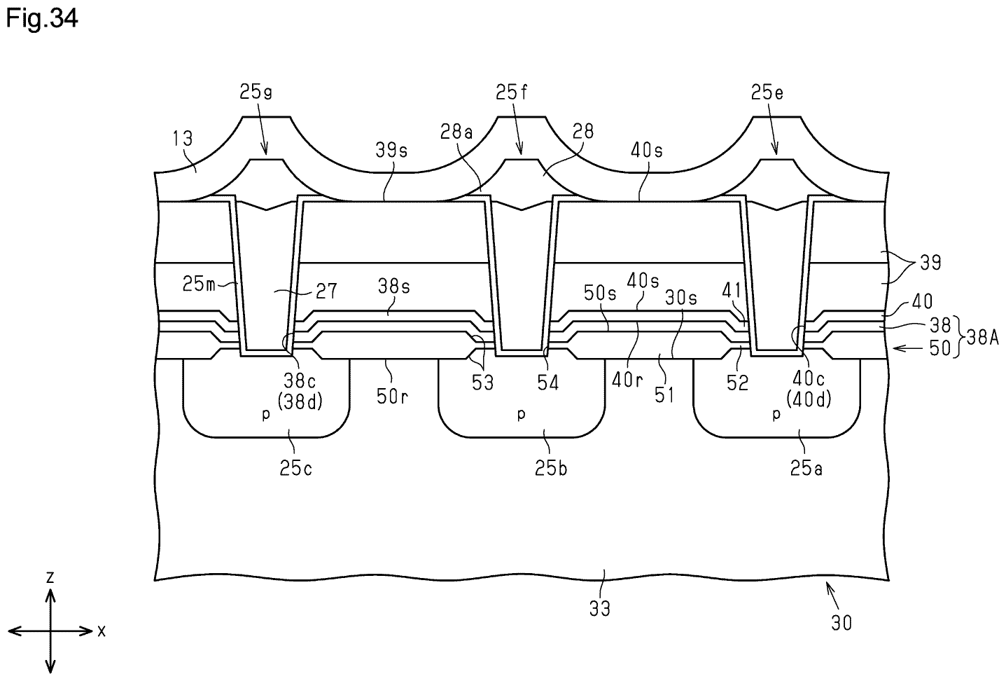

In the third embodiment, as shown in FIG. 34, the barrier layer 40 may be formed on the surface 38s of the insulation film 38 as in the second embodiment. In this case, the barrier layer 40 is sandwiched between the insulation film 38 and the intermediate insulation film 39. The barrier layer 40 is formed in conformance with the shape of the surface 38s of the insulation film 38. For the sake of convenience, FIG. 34 does not show hatching of the components of the semiconductor device 10.

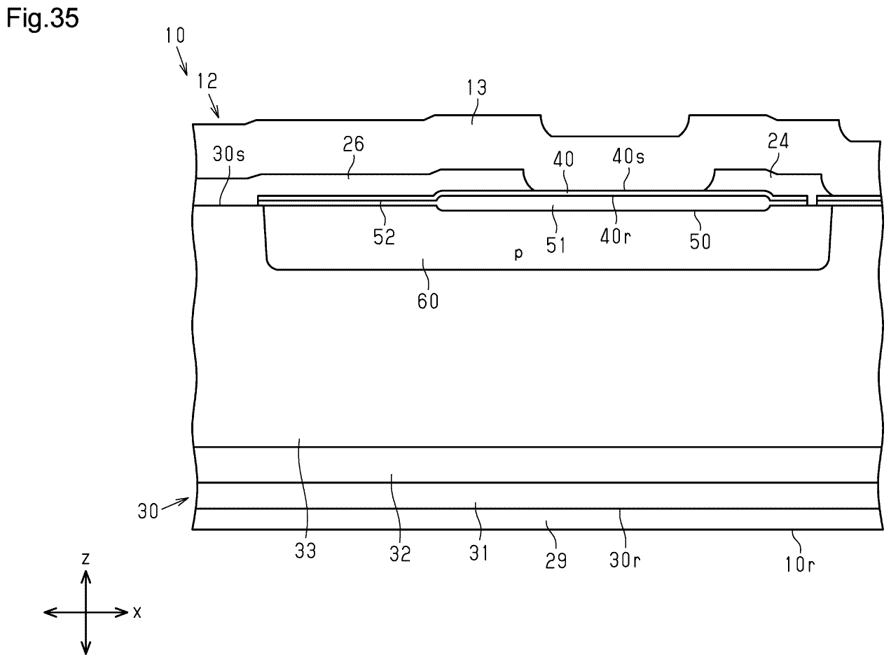

In each embodiment, the termination structure in the peripheral region 12 that reduces a surface electric field is not limited to the FLR portion 25. For example, as shown in FIG. 35, the semiconductor device 10 may include, instead of the FLR portion 25, a looped semiconductor region 60 of a second conductive type extending in a direction orthogonal to the z-direction in a portion of the peripheral region 12 between the gate electrode 22 and the gate fingers 23A and 23B (refer to FIG. 2) and the equipotential ring 26. The semiconductor region 60 has a width that is greater than the width of the guard rings 25a to 25d (dimension of the guard rings 25a to 25d in a direction orthogonal to the z-direction). The concentration of the dopant in the semiconductor region 60 is lower than, for example, that in the p⁺-type contact region 34B or the base contact region 37. The concentration of the dopant in the semiconductor region 60 is equal to that in the guard rings 25a to 25d. For the sake of convenience, FIG. 35 does not show hatching of the components of the semiconductor device 10.

In the example shown, the width of the emitter extension 24 (dimension of the emitter extension 24 in a direction orthogonal to the z-direction) is greater than the width of the emitter extension 24 in each embodiment. As viewed in the z-direction, the emitter extension 24 portion partially overlaps the semiconductor region 60.

In the example shown, the semiconductor region 60 extends to the region in which the equipotential ring 26 is formed. As viewed in the z-direction, the semiconductor region 60 extends to a position at which the semiconductor region 60 overlaps the equipotential ring 26. Thus, the semiconductor region 60 includes a region in which the semiconductor region 60 overlaps the emitter extension 24 as viewed in the z-direction, a region in which the semiconductor region 60 overlaps the equipotential ring 26 as viewed in the z-direction, and a region between the emitter extension 24 and the equipotential ring 26. In this structure, the semiconductor region 60 reduces a surface electric field in the peripheral region 12, thereby improving the dielectric strength of the semiconductor device 10.

In each embodiment, the formation range of the barrier layer 40 may be changed in any manner. In an example, the barrier layer 40 may be omitted from the cell region 11. That is, the barrier layer 40 may be formed in only the peripheral region 12. The barrier layer 40 may be omitted from at least one of the gate fingers 23A and 23B, the emitter extension 24, and the equipotential ring 26 in the peripheral region 12.

In each embodiment, the intermediate insulation film 39 is formed of a single layer. However, there is no limit to such a configuration. The intermediate insulation film 39 may have a structure in which different types of insulation films are stacked one another.

In each embodiment, the gate trenches 22A and the emitter trenches 21A are alternately arranged. However, there is no limit to such arrangement. The arrangement of the gate trenches 22A and the emitter trenches 21A may be changed in any manner.

In each embodiment, the semiconductor device 10 includes the gate trenches 22A and the emitter trenches 21A. However, there is no limit to such a configuration. In an example, the emitter trenches 21A may be omitted from the semiconductor device 10.

In each embodiment, the first part 27 and the second part 28 of the field plates 25e to 25h of the FLR portion 25 may be formed integrally with each other. In this case, the first part 27 is formed from AlCu instead of tungsten (W). The emitter electrode 21, the gate fingers 23A and 23B, and the emitter extension 24 may also be changed in the same manner as the field plates 25e to 25h.

In each embodiment, the semiconductor device 10 may be a planar gate IGBT instead of a trench gate IGBT.

In each embodiment, the semiconductor device 10 is embodied as an IGBT. Alternatively, the semiconductor device 10 may be, for example, a silicon carbide metal-oxide-semiconductor field-effect transistor (SiC MOSFET) or a Si MOSFET.

In the present disclosure, the term “on” includes the meaning of “above” in addition to the meaning of “on” unless otherwise clearly indicated in the context. Thus, the phrase “A is formed on B” is intended to mean that A may be disposed directly on B in contact with B in the present embodiment and also that A may be disposed above B without contacting B in a modified example. In other words, the term “on” does not exclude a structure in which another member is formed between A and B.

The z-direction as referred to in the present disclosure does not necessarily have to be the vertical direction and does not necessarily have to fully conform to the vertical direction. In the structures according to the present disclosure, “upward” and “downward” in the z-direction as referred to in the present description are not limited to “upward” and “downward” in the vertical direction. In an example, the x-direction may conform to the vertical direction. In another example, the y-direction may conform to the vertical direction.

### Clauses

The technical aspects that are understood from the embodiments and the modified examples will be described below. The reference signs of the elements in the embodiments are given to the corresponding elements in clauses with parentheses. The reference signs used as examples to facilitate understanding, and the elements in each clause are not limited to those elements given with the reference signs.

[Clause 1] A semiconductor device (10), including:
a cell region (11) including cells (11A); and
a peripheral region (12) arranged at an outer side of the cell region (11) and surrounding the cell region (11), where
the peripheral region (12) includes:
   a first semiconductor layer (33) of a first conductive type;
   a second semiconductor region (25a to 25d) of a second conductive type partially formed on the first semiconductor layer (33);
   an insulation film (38A, 39) covering a surface (30s) of the first semiconductor layer (33) and a surface (30s) of the second semiconductor region (25a to 25d);
   an opening (38c, 39c) formed in the insulation film (38A, 39) and partially exposing the surface (30s) of the second semiconductor region (25a to 25d);
   an electrode (25e to 25h) in contact with a portion exposed from the opening (38c, 39c); and
   a passivation film (13) covering the insulation film (38A, 39) and the electrode (25e to 25h),
the electrode (25e to 25h) includes:
   a first part (27) arranged in the opening (38c, 39c); and
   a second part (28) including a projection (28a) projecting sideward from the first part (27) and overlapping with the insulation film (38A, 39),
the semiconductor device (10) further includes a barrier layer (40) arranged between the passivation film (13) and the first semiconductor layer (33) and having a smaller diffusion coefficient than the insulation film (38A, 39) and the passivation film (13), and
the barrier layer (40) includes a portion arranged between the projection (28a) and the second semiconductor region (25a to 25d).

[Clause 2] The semiconductor device according to clause 1, where
the barrier layer (40) is formed on a surface (38s) of the insulation film (38A, 39), and
the barrier layer (40) includes a portion sandwiched between the insulation film (38A, 39) and the projection (28a).

[Clause 3] The semiconductor device according to clause 2, where
the insulation film (38A, 39) includes:
   a first insulation film (38A) formed on the surface (30s) of the first semiconductor layer (33) and the surface (30s) of the second semiconductor region (25a to 25d); and
   a second insulation film (39) formed on the first insulation film (38A), and
the barrier layer (40) is formed on a surface (39s) of the second insulation film (39) and is covered by the passivation film (13).

[Clause 4] The semiconductor device according to clause 1, where
the insulation film (38A, 39) includes:
   a first insulation film (38A) formed on the surface (30s) of the first semiconductor layer (33) and the surface (30s) of the second semiconductor region (25a to 25d); and
   a second insulation film (39) formed on the first insulation film (38A),
the barrier layer (40) is formed on a surface (38s) of the first insulation film (38A) and is covered by the second insulation film (39), and
the second insulation film (39) is covered by the passivation film (13).

[Clause 5] The semiconductor device according to clause 3 or 4, where
a portion of the first insulation film (38A) defining the opening (38c) is inclined toward the first semiconductor layer (33) as the opening (38c) becomes closer, and
the second insulation film (39) covers the portion of the first insulation film (38A) defining the opening (38c).

[Clause 6] The semiconductor device according to any one of clauses 1 to 5, where
the barrier layer (40) includes a wall surface (40d) defining a barrier layer opening (40c) into which the first part (27) is inserted, and
the wall surface (40d) defining the barrier layer opening (40c) is flush with a wall surface (38d, 39d) of the insulation film (38A, 39) defining the opening (38c, 39c).

[Clause 7] The semiconductor device according to any one of clauses 1 to 6, where the barrier layer (40) extends over an outer edge of the second semiconductor region (25a to 25d) as viewed in a thickness-wise direction (z-direction) of the first semiconductor layer (33).

[Clause 8] The semiconductor device according to any one of clauses 1 to 7, where a thickness of the barrier layer (40) is less than a thickness of the insulation film (38A, 39).

[Clause 9] The semiconductor device according to clause 2 or 3, where
the cell region (11) is a region in which a transistor is formed,
the cell region (11) includes:
   the first semiconductor layer (33);
   a gate oxide film (38) formed on a surface (30s) of the first semiconductor layer (33); and
   an intermediate insulation film (39) formed on a surface (38a) of the gate oxide film (38), and
the barrier layer (40) is formed on a surface (39s) of the intermediate insulation film (39).

[Clause 10] The semiconductor device according to clause 4, where
the cell region (11) is a region in which a transistor is formed,
the cell region (11) includes:
   the first semiconductor layer (33);
   a gate oxide film (38) formed on the surface (30s) of the first semiconductor layer (33); and
   an intermediate insulation film (39) formed on the gate oxide film (38), and
the barrier layer (40) is formed in the cell region (11) between the gate oxide film (38) and the intermediate insulation film (39).

[Clause 11] The semiconductor device according to any one of clauses 1 to 10, where the peripheral region (12) includes a semiconductor region (25a to 25d, 60) of a second conductive type to reduce a surface electric field.

[Clause 12] The semiconductor device according to any one of clauses 1 to 11, where
the insulation film (38A, 39) is a silicon oxide film,
the passivation film (13) is an organic insulation film, and
the barrier layer (40) is a silicon nitride film.

[Clause 13] A method for manufacturing a semiconductor device that includes a cell region (11) including cells (11A) and a peripheral region (12) arranged at an outer side of the cell region (11) and surrounding the cell region (11), the method including:
forming a first semiconductor layer (33) of a first conductive type in the peripheral region (12);
partially forming a second semiconductor region (834) of a second conductive type on the first semiconductor layer (33);
forming an insulation film (838B, 838, 839) covering a surface (830s) of the first semiconductor layer (33) and a surface (830s) of the second semiconductor region (834);
forming a barrier layer (840) on a surface (839s) of the insulation film (839), the barrier layer (840) having a smaller diffusion coefficient than the insulation film (838B, 838, 839);
forming an opening (861 to 863) extending through the insulation film (838B, 838, 839) and the barrier layer (840) to partially expose the second semiconductor region (834);
forming an electrode (25e to 25h) including a first part (821) arranged in the opening (861 to 863) and a second part (822) including a projection projecting sideward from the first part (821) and overlapping with the insulation film (838B, 838, 839) and the barrier layer (840); and
forming a passivation film that covers the barrier layer (840) and the electrode.

[Clause 14] The method according to clause 13, where the forming an insulation film (838B, 838, 839) includes:
forming a first insulation film (838B, 838) by thermally oxidizing the surface (830s) of the first semiconductor layer (33); and
forming a second insulation film (839) by chemical vapor deposition (CVD) of a surface of the first insulation film (838).

[Clause 15] The method according to clause 14, where the forming a first insulation film (838B, 838) includes:
forming a mask (852) on a portion of the surface (830s) of the first semiconductor region (33); and
forming an oxide film (851) by oxidizing the portion of the surface (830s) of the first semiconductor region (33) exposed from the mask (852).

[Clause 16] The method according to clause 14, where the forming a first insulation film (838B) includes:
forming a first insulation layer by thermally oxidizing the surface (830s) of the first semiconductor layer (33); and
wet-etching the first insulation layer and then dry-etching the first insulation layer.

[Clause 17] A method for manufacturing a semiconductor device (10) that includes a cell region (11) including cells (11A) and a peripheral region (12) arranged at an outer side of the cell region (11) and surrounding the cell region (11), the method including:
forming a first semiconductor layer (33) of a first conductive type in the peripheral region (12);
partially forming a second semiconductor region (834) of a second conductive type on the first semiconductor layer (33);
forming a first insulation film (838B, 838) covering a surface (830s) of the first semiconductor layer (33) and a surface (830s) of the second semiconductor region (834);
forming a barrier layer (840) on a surface (838s) of the first insulation film (838), the barrier layer (840) having a smaller diffusion coefficient than the first insulation film (838B, 838);
forming a second insulation film (839) that covers a surface (840s) of the barrier layer (840);
forming an opening (861) extending through the first insulation film (838B, 838), the second insulation film (839), and the barrier layer (840) to partially expose the second semiconductor region (834);
forming an electrode (25e to 25h) including a first part (821) arranged in the opening (861) and a second part (822) including a projection projecting sideward from the first part (821) and overlapping with the second insulation film (839) and the barrier layer (840); and
forming a passivation film (13) that covers the second insulation film (839) and the electrode.

[Clause 18] The method according to clause 17, where
the forming a first insulation film (838B, 838) includes thermally oxidizing the surface (830s) of the first semiconductor layer (33), and
the forming a second insulation film (839) includes forming the second insulation film (839) by CVD on a surface (840s) of the barrier layer (840).

[Clause 19] The method according to clause 18, where the forming a first insulation film (838B) includes:
forming a mask (852) on a portion of the surface (830s) of the first semiconductor layer (33); and
forming an oxide film (851) by oxidizing the portion of the surface (830s) of the first semiconductor layer (33) exposed from the mask (852).

[Clause 20] The method according to clause 18, where the forming a first insulation film (838B) includes:
forming a first insulation layer by thermally oxidizing the surface (830s) of the first semiconductor layer (33) and the surface (830s) of the second semiconductor region (834); and
wet-etching the first insulation layer and then dry-etching the first insulation layer.

### REFERENCE SIGNS LIST

10) semiconductor device
11) cell region
12) peripheral region
13) passivation film
23A, 23B) gate finger
23ba) first part
23bb) second part
23bc) projection
24) emitter extension
24a) first part
24b) second part
24c) projection
25a to 25d) guard ring (second semiconductor region of second conductive type)
25e to 25h) field plate (electrode)
27) first part
28) second part
28a) projection
33) drift layer (first semiconductor region of first conductive type)
38) insulation film (gate oxide film)
38A) insulation film (first insulation film)
38s) surface
38a, 38c, 38g, 38p) opening
38d, 38h) wall surface
39) intermediate insulation film (second insulation film)
39s) surface
39a, 39c, 39e, 39g, 39p, 39u) opening
39b, 39d, 39f, 39h, 39q, 39t) wall surface
40) barrier layer
40s) surface
40a, 40c, 40e, 40g, 40p, 40u) barrier layer opening
40b, 40d, 40f, 40h, 40q, 40t) wall surface
41) intermediate portion
50) LOCOS oxide film
54) opening
821) first part
822) second part
830) semiconductor substrate
838) insulation film
838s) surface
839) intermediate insulation film
839s) surface
840) barrier layer
840s) surface
851) oxide film
851s) surface
852) mask
861 to 863) opening

1. A semiconductor device, comprising:
a cell region including cells; and
a peripheral region arranged at an outer side of the cell region and surrounding the cell region, wherein
the peripheral region includes:
a first semiconductor layer of a first conductive type;
a second semiconductor region of a second conductive type partially formed on the first semiconductor layer;
an insulation film covering a surface of the first semiconductor layer and a surface of the second semiconductor region;
an opening formed in the insulation film and partially exposing the surface of the second semiconductor region;
an electrode in contact with a portion exposed from the opening; and
a passivation film covering the insulation film and the electrode, the electrode includes:
a first part arranged in the opening; and
a second part including a projection projecting sideward from the first part and overlapping with the insulation film,
the semiconductor device further comprises a barrier layer arranged between the passivation film and the first semiconductor layer and having a smaller diffusion coefficient than the insulation film and the passivation film, and
the barrier layer includes a portion arranged between the projection and the second semiconductor region.

2. The semiconductor device according to claim 1, wherein
the barrier layer is formed on a surface of the insulation film, and
the barrier layer includes a portion sandwiched between the insulation film and the projection.

3. The semiconductor device according to claim 2, wherein
the insulation film includes:
a first insulation film formed on the surface of the first semiconductor layer and the surface of the second semiconductor region; and
a second insulation film formed on the first insulation film, and
the barrier layer is formed on a surface of the second insulation film and is covered by the passivation film.

4. The semiconductor device according to claim 1, wherein
the insulation film includes:
a first insulation film formed on the surface of the first semiconductor layer and the surface of the second semiconductor region; and
a second insulation film formed on the first insulation film,
the barrier layer is formed on a surface of the first insulation film and is covered by the second insulation film, and
the second insulation film is covered by the passivation film.

5. The semiconductor device according to claim 3, wherein
a portion of the first insulation film defining the opening is inclined toward the first semiconductor layer as the opening becomes closer, and
the second insulation film covers the portion of the first insulation film defining the opening.

6. The semiconductor device according to claim 1, wherein
the barrier layer includes a wall surface defining a barrier layer opening into which the first part is inserted, and
the wall surface defining the barrier layer opening is flush with a wall surface of the insulation film defining the opening.

7. The semiconductor device according to claim 1, wherein the barrier layer extends over an outer edge of the second semiconductor region as viewed in a thickness-wise direction of the first semiconductor layer.

8. The semiconductor device according to claim 1, wherein a thickness of the barrier layer is less than a thickness of the insulation film.

9. The semiconductor device according to claim 2, wherein
the cell region is a region in which a transistor is formed,
the cell region includes:
the first semiconductor layer;
a gate oxide film formed on the surface of the first semiconductor layer; and
an intermediate insulation film formed on a surface of the gate oxide film, and
the barrier layer is formed on a surface of the intermediate insulation film.

10. The semiconductor device according to claim 4, wherein
the cell region is a region in which a transistor is formed,
the cell region includes:
the first semiconductor layer;
a gate oxide film formed on the surface of the first semiconductor layer; and
an intermediate insulation film formed on the gate oxide film, and
the barrier layer is formed in the cell region between the gate oxide film and the intermediate insulation film.

11. The semiconductor device according to claim 1, wherein the peripheral region includes a semiconductor region of a second conductive type to reduce a surface electric field.

12. The semiconductor device according to claim 1, wherein
the insulation film is a silicon oxide film,
the passivation film is an organic insulation film, and
the barrier layer is a silicon nitride film.

13. A method for manufacturing a semiconductor device that includes a cell region including cells and a peripheral region arranged at an outer side of the cell region and surrounding the cell region, the method comprising:
forming a first semiconductor layer of a first conductive type in the peripheral region;
partially forming a second semiconductor region of a second conductive type on the first semiconductor layer;
forming an insulation film covering a surface of the first semiconductor layer and a surface of the second semiconductor region;
forming a barrier layer on a surface of the insulation film, the barrier layer having a smaller diffusion coefficient than the insulation film;
forming an opening extending through the insulation film and the barrier layer to partially expose the second semiconductor region;
forming an electrode including a first part arranged in the opening and a second part including a projection projecting sideward from the first part and overlapping with the insulation film and the barrier layer; and
forming a passivation film that covers the barrier layer and the electrode.

14. The method according to claim 13, wherein the forming an insulation film includes:
forming a first insulation film by thermally oxidizing the surface of the first semiconductor layer; and
forming a second insulation film by chemical vapor deposition of a surface of the first insulation film.

15. The method according to claim 14, wherein the forming a first insulation film includes:
forming a mask on a portion of the surface of the first semiconductor layer; and
forming an oxide film by oxidizing the portion of the surface of the first semiconductor layer exposed from the mask.

16. The method according to claim 14, wherein the forming a first insulation film includes:
forming a first insulation layer by thermally oxidizing the surface of the first semiconductor layer; and
wet-etching the first insulation layer and then dry-etching the first insulation layer.

17. A method for manufacturing a semiconductor device that includes a cell region including cells and a peripheral region arranged at an outer side of the cell region and surrounding the cell region, the method comprising:
forming a first semiconductor layer of a first conductive type in the peripheral region;
partially forming a second semiconductor region of a second conductive type on the first semiconductor layer;
forming a first insulation film covering a surface of the first semiconductor layer and a surface of the second semiconductor region;
forming a barrier layer on a surface of the first insulation film, the barrier layer having a smaller diffusion coefficient than the first insulation film;
forming a second insulation film that covers a surface of the barrier layer;
forming an opening extending through the first insulation film, the second insulation film, and the barrier layer to partially expose the second semiconductor region;
forming an electrode including a first part arranged in the opening and a second part including a projection projecting sideward from the first part and overlapping with the second insulation film and the barrier layer; and
forming a passivation film that covers the second insulation film and the electrode.

18. The method according to claim 17, wherein
the forming a first insulation film includes thermally oxidizing the surface of the first semiconductor layer, and
the forming a second insulation film includes forming the second insulation film by CVD on a surface of the barrier layer.

19. The method according to claim 18, wherein the forming a first insulation film includes:
forming a mask on a portion of the surface of the first semiconductor layer; and
forming an oxide film by oxidizing the portion of the surface of the first semiconductor layer exposed from the mask.

20. The method according to claim 18, wherein the forming a first insulation film includes:
forming a first insulation layer by thermally oxidizing the surface of the first semiconductor layer; and
wet-etching the first insulation layer and then dry-etching the first insulation layer.
